(19) United States
(12) Patent Application Publication
(10) Pub. No.: US 2026/0211582 A1
(43) Pub. Date: Jul. 23, 2026

(54) NON-VOLATILE DEVICE, STORAGE DEVICE AND METHOD OF OPERATING THE STORAGE DEVICE

(71) Applicant: Samsung Electronics Co., Ltd., Suwon-si (KR)

(72) Inventors: Ilyoung Jin, Suwon-si (KR); Tongsung Kim, Suwon-si (KR)

(21) Appl. No.: 19/407,594

(22) Filed: Dec. 3, 2025

(30) Foreign Application Priority Data
Jan. 23, 2025 (KR) 10-2025-0010701

(51) Int. Cl. G06F 3/06

(52) U.S. Cl. CPC G06F 3/0659; G06F 3/0604; G06F 3/0679

(57) ABSTRACT

Provided are a non-volatile memory device, a storage device, and a method of operating the storage device. The non-volatile memory device includes a data pin where data signal is output, a command address pin separated from the data pin and configured to receive a NTO (Non-Target On Die Termination) enable command for a non-target termination resistance of the data pin and a select chip enable command for an output operation of the data signal, and an on die termination circuit configured to set a termination resistor for the data pin to the non-target termination resistance, in response to a logical operation of NTO enable data based on the NTO enable command and select chip enable data based on the select chip enable command.

### CROSS-REFERENCE TO RELATED APPLICATION

This application claims priority to and the benefit of Korean Patent Application No. 10-2025-0010701, filed on Jan. 23, 2025, with the Korean Patent Office, the entire contents of which are incorporated herein by reference.

### BACKGROUND

### (a) Field

The present disclosure relates to non-volatile memory devices, storage devices, and methods of operating the storage devices.

### (b) Description of the Related Art

A storage device includes a plurality of non-volatile memory devices and a storage controller that controls the plurality of non-volatile memory devices. Each of the plurality of non-volatile memory devices reduces signal reflections that occur during the process of transmitting and receiving a data signal with the storage controller through an on die termination (ODT) circuit.

The plurality of non-volatile memory devices may be divided into target memory devices and non-target memory devices depending on whether input/output operations are performed. As the plurality of non-volatile memory devices are divided into target memory devices and non-target memory devices, the on die termination circuit may operate in various ways, and the operation of the on die termination circuit may be controlled by a command provided from the storage controller

### SUMMARY

Some embodiments provide non-volatile memory devices, storage devices, and methods of operating storage devices that improve the efficiency of data input/output operations.

Some embodiments provide non-volatile memory devices, storage devices, and methods of operating storage devices that perform advantageous operations depending on input/output conditions.

According to an embodiment disclosed, non-volatile memory device includes a data pin configured to output a data signal, a command address pin separated from the data pin and configured to receive a NTO (Non-Target On Die Termination) enable command for a non-target termination resistance of the data pin and a select chip enable command for an output operation of the data signal, and an on die termination circuit configured to set a termination resistor for the data pin to the non-target termination resistance, in response to a logical operation of NTO enable data based on the NTO enable command and select chip enable data based on the select chip enable command.

According to an embodiment disclosed, storage device includes a first non-volatile memory device including a first data pin, a first command address pin separated from the first data pin, and a first on die termination circuit, a second non-volatile memory device including a second data pin electrically connected to the first data pin through a channel, a second command address pin separated from the second data pin, and a second on die termination circuit, and a storage controller configured to provide an NTO enable command for enabling an NTO operation of the first on die termination circuit and the second on die termination circuit to the first non-volatile memory device and the second non-volatile memory device, respectively, through the first command address pin and the second command address pin to enable an NTO operation for the first data pin, and provide a first select chip enable command for an output operation of the first data pin through the first command address pin to control the first on die termination circuit to disable the NTO operation for the first data pin.

According to an embodiment disclosed, method of operating a storage device includes providing a read command to a first non-volatile memory device and a second non-volatile memory device sharing a channel with each other, providing an NTO (Non-Target On Die Termination) enable command to the first non-volatile memory device and the second non-volatile memory device through a first command address pin of the first non-volatile memory device and a second command address pin of the second non-volatile memory device to enable an NTO operation for a first data pin separated from the first command address pin in the first non-volatile memory device and an NTO operation for a second data pin separated from the second command address pin in the second non-volatile memory device, providing a first select chip enable command for an output operation of the first data pin through the first command address pin to disable an NTO operation for the first data pin and enable a self-termination operation for the first data pin, outputting a first data signal from the first data pin of the first non-volatile memory device, and providing a first select chip terminate command corresponding to the first select chip enable command through the first command address pin to disable the self-termination operation for the first data pin and enable the NTO operation for the first data pin.

According to embodiment disclosed, non-volatile memory device includes a data pin configured to output a data signal, a command address pin separated from the data pin and configured to receive a NTO (Non-Target On Die Termination) enable command for a non-target termination resistance of the data pin, a NTO pin separated from the data pin and the command address pin and configured to receive an NTO signal for the non-target termination resistance, and an on die termination circuit configured to set a termination resistor for the data pin to the non-target termination resistance in response to a logic operation on NTO data based on the NTO signal and NTO enable data based on the NTO enable command

### BRIEF DESCRIPTION OF THE DRAWINGS

FIG. 1 is a block diagram illustrating a storage system according to some embodiments.

FIG. 2 is a block diagram illustrating a storage device according to some embodiments.

FIG. 3 is a diagram illustrating a storage device according to some embodiments.

FIG. 4 is a block diagram illustrating a storage controller according to some embodiments.

FIG. 5 is a block diagram and FIG. 6 is a table illustrating on die termination circuits according to some embodiments.

FIG. 7 is a block diagram illustrating a non-target ODT circuit according to some embodiments.

FIG. 8 is a block diagram illustrating a non-target ODT enable circuit according to some embodiments.

FIG. 9 is a block diagram illustrating a non-volatile memory device according to some embodiments.

FIG. 10 is a schematic of a three-dimensional structure of a memory cell array according to some embodiments.

FIG. 11 is a flowchart illustrating a method of operating a storage device according to some embodiments.

FIG. 12 is a timing diagram illustrating a method of operating a storage device according to some embodiments.

FIG. 13 is a block diagram illustrating a storage device according to some embodiments.

FIG. 14 is a block diagram illustrating a non-target ODT circuit according to some embodiments.

FIG. 15 is a block diagram illustrating a non-target ODT enable circuit according to some embodiments.

FIG. 16 is a flowchart illustrating a method of operating a storage device according to some embodiments.

FIG. 17 is a timing diagram illustrating a method of operating a storage device according to some embodiments.

FIG. 18 is a block diagram illustrating a non-target ODT circuit according to some embodiments.

FIG. 19 is a block diagram illustrating a non-target ODT enable circuit according to some embodiments.

FIG. 20 is a flowchart illustrating a method of operating a storage device according to some embodiments.

FIG. 21 is a timing diagram illustrating a method of operating a storage device according to some embodiments.

FIG. 22 is a block diagram illustrating an SSD system to which a storage device is applied according to some embodiments.

FIG. 23 is a block diagram illustrating a data center to which a storage device according to some embodiments is applied

### DETAILED DESCRIPTION OF THE EMBODIMENTS

Hereinafter, various embodiments of the present disclosure will be described in detail with reference to the attached drawings so that a person having ordinary skill in the art to which the present disclosure pertains may easily implement the disclosure. The present disclosure may be embodied in many different forms and is not limited to the embodiments described herein.

To clearly explain the present disclosure, parts irrelevant to the description are omitted, and identical or similar reference numerals are given to identical or similar components throughout the specification.

In addition, the size and thickness of each component shown in the drawings are arbitrarily shown for convenience of explanation, so the present disclosure is not necessarily limited to what is shown.

Additionally, throughout the specification, whenever a part is said to “include” a component, this does not mean that it excludes other components, but rather that it may include other components, unless otherwise specifically stated.

Additionally, a specific number set forth in a claim, even if explicitly recited in the claim, should not be construed as meaning that there is limitation to the specific number in the claim where such recitation does not exist. For example, subsequent dependent claims may include the phrases “at least one” and “one or more” to aid understanding. However, the use of this construction should not be understood as a limitation described by the indefinite article ‘one’ for the sake of one example.

Moreover, when a convention such as ‘at least one of A, B, or C’ is used, such a phrase will be well understood by a person skilled in the art (i.e., ‘a system comprising at least one of A, B, or C’ includes, but is not limited to, A alone, B alone, C alone, A and B, A and C, B and C, and/or A, B, and C together). Or, words and/or phrases in the detailed description or claims or drawings having two or more separate alternative terms should be considered as possibly including one, or either, or both terms. For example, the phrase ‘A or B’ should be understood to include the possibilities of ‘A’, or ‘B’, or ‘A and B’. As used herein, the term “and/or” includes any and all combinations of one or more of the associated listed items.

The terms “module,” “unit,” “part,” etc., used in this document are terms intended to refer to a component that performs at least one function or operation, and such a component may be implemented as hardware or software, or as a combination of hardware and software.

It is noted that aspects described with respect to one embodiment may be incorporated in different embodiments although not specifically described relative thereto. That is, all embodiments and/or features of any embodiments can be combined in any way and/or combination.

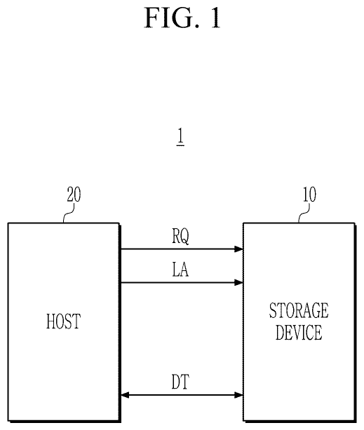

FIG. 1 is a block diagram illustrating a storage system according to some embodiments.

Referring to FIG. 1, a storage system 1 may include a host device 20 and a storage device 10. According to an embodiment, the storage system 1 may be provided as one of computing systems, such as an Ultra Mobile PC (UMPC), a workstation, a net-book, a PDA(Personal Digital Assistants), a portable computer, a web tablet, a wireless phone, a mobile phone, a smart phone, an e-book, a Portable Multimedia Player (PMP), a portable game console, a navigation device, a black box, a digital camera, a DMB (Digital Multimedia Broadcasting) player, a digital audio recorder, a digital audio player, a digital picture recorder, a digital picture player, a digital video recorder, a digital video player, a server, and a data center.

The host device 20 may provide an operation request RQ and a logical address LA to the storage device 10 and transmit and receive data DT with the storage device 10. The operation request RQ may include an input/output request including a write request for data DT and a read request for data DT, and a set request for a storage device 10.

The host device 20 may provide input/output requests in various input/output patterns. For example, the host device 20 may provide a write request to the storage device 10 in a sequential write pattern with logical addresses LA being consecutive, and may provide a write request and a read request to the storage device 10 in a read after write pattern with respect to data DT having the same logical address LA. Additionally, the host device 20 may provide a read request to the storage device 10 in a sequential read pattern with consecutive logical addresses LA. The setup request may include requests for creation and modification of a namespace, and status reporting of a storage device 10, but the technical idea of the present disclosure is not limited thereto.

A logical address LA may be an address from a logical perspective managed from the perspective of a host device 20 and may be referred to as a Logical Block Address (LBA). For example, the size of data DT defined by one logical address LA may be, but is not limited to, 512B or 4KB. Additionally, the host device 20 may provide a namespace ID along with a logical address LA to the storage device 10.

The host device 20 may exchange data, etc., with the storage device 10 based on at least one of various interface protocols, such as the PCI-E protocol, the NVMe protocol, the PCI protocol, the USB (Universal Serial Bus) protocol, the MMC (Multi-Media Card) protocol, the ATA (Advanced Technology Attachment) protocol, the Serial-ATA protocol, the Parallel-ATA protocol, the SCSI (Small Computer Small Interface) protocol, the ESDI (Enhanced Small Disk Interface) protocol, the IDE (Integrated Drive Electronics) protocol, the MIPI (Mobile Industry Processor Interface) protocol, the UFS (Universal Flash Storage) protocol, etc.

The storage device 10 may receive an operation request RQ and a logical address LA from the host device 20, and transmit and receive data DT with the host device 20. According to some embodiments, the storage device 10 includes a non-volatile memory device, which is a NAND Flash Memory, and the non-volatile memory device may include a plurality of memory blocks that store data DT. According to some embodiments, the storage device 10 operates based on the NVMe protocol and may support the plurality of namespaces. NVMe is a register-level interface that communicates between a storage device 10, such as a solid state drive (hereinafter referred to as SSD), and the software of a host device 20. It is based on a physical/transport layer, such as PCI-E or CXL, and may be an interface optimized for SSD.

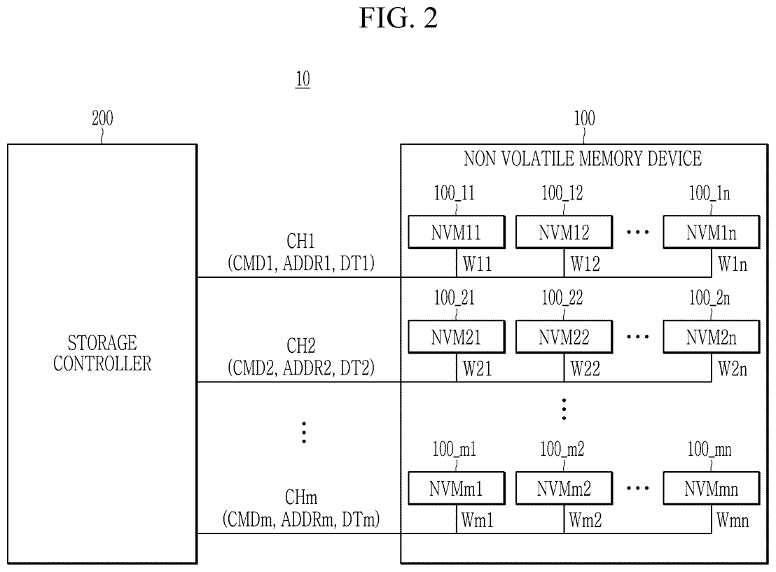

FIG. 2 is a block diagram illustrating a storage device according to some embodiments.

Referring to FIG. 2, the storage device 10 may include a non-volatile memory device 100 and a storage controller 200. The storage device 10 may support the plurality of channels CH1 to CHm, and the non-volatile memory device 100 and the storage controller 200 may be connected through the plurality of channels CH1 to CHm. For example, the storage device 10 may be implemented as a storage device such as an SSD.

A non-volatile memory device 100 may include a plurality of non-volatile memory devices 100_11 to 100_mn. Each of the plurality of non-volatile memory devices 100_11 to 100_mn may be connected to one of the plurality of channels CH1 to CHm through a corresponding way. For example, the 1-1 to 1-n non-volatile memory devices 100_11 to 100_1n may be connected to the first channel CH1 through ways W11 to W1n, and the 2-1 to 2-n non-volatile memory devices 100_21 to 100_2n may be connected to the second channel CH2 through ways W21 to W2n. In an embodiment, each of the plurality of non-volatile memory devices 100_11 to 100_mn may be implemented as any memory unit that may operate according to individual control signals from the storage controller 200. For example, each of the plurality of non-volatile memory devices 100_11 to 100_mn may be a logical unit number LUN capable of processing commands and status reports, and may be implemented as a chip or a die, but embodiments are not limited thereto.

The storage controller 200 may transmit and receive signals with the non-volatile memory device 100 through the plurality of channels CH1 to CHm. For example, the storage controller 200 may transmit commands CMD1 to CMDm and addresses ADDR1 to ADDRm to the non-volatile memory device 100 through channels CH1 to CHm, and transmit and receive data DT1 to DTm with the non-volatile memory device 100.

The storage controller 200 may select one of the non-volatile memory devices connected to one channel and transmit and receive signals with the selected non-volatile memory device. For example, the storage controller 200 may select the 1-1 non-volatile memory device 100_11 among the 1-1 to 1-n non-volatile memory devices 100_11 to 100_1n by transmitting a select chip enable command for the 1-1 non-volatile memory device 100_11 through the first channel CH1. The selected 1-1 non-volatile memory device 100_11 may input/output the first data DT1, and among the 1-1 to 1-n non-volatile memory devices 100_11 to 100_1n connected to the first channel CH1, the 1-1 non-volatile memory device 100_11 is a target memory device, and the remaining 1-2 to 1-n non-volatile memory devices 100_12 to 100_1n may be non-target memory devices.

The storage controller 200 may transmit and receive signals in parallel with the non-volatile memory device 100 through different channels. For example, the storage controller 200 may transmit a first command CMD1 to the non-volatile memory device 100 through a first channel CH1 while transmitting a second command CMD2 to the non-volatile memory device 100 through a second channel CH2. For example, the storage controller 200 may receive first data DT1 from the non-volatile memory device 100 through the first channel CH1 while receiving second data DT2 from the memory device 100 through the second channel CH2.

The storage controller 200 may control the overall operation of the non-volatile memory device 100. The storage controller 200 may control each of a plurality of non-volatile memory devices 100_11 to 100_mn connected to a plurality of channels CH1 to CHm by transmitting signals to a plurality of channels CH1 to CHm. For example, the storage controller 200 may control a selected one of the non-volatile memory devices 100_11 to 100_1n by transmitting a first command CMD1 and a first address ADDR1 to a first channel CH1.

Each of the plurality of non-volatile memory devices 100_11 to 100_mn may operate under the control of the storage controller 200. For example, the 1-1 non-volatile memory device 100_11 may program first data DT1 based on a first command CMD1, a first address ADDR1, and first data DT1 provided to a first channel CH1. For example, the 2-1 non-volatile memory device 100_21 may read second data DT2 based on a second command CMD2 and a second address ADDR2 provided through a second channel CH2, and transmit the read second data DT2 to the storage controller 200.

In FIG. 2, a non-volatile memory device 100 is illustrated as communicating with a storage controller 200 through m channels, and the non-volatile memory device 100 includes n non-volatile memory devices corresponding to each channel, but the number of channels and the number of non-volatile memory devices connected to one channel may be varied.

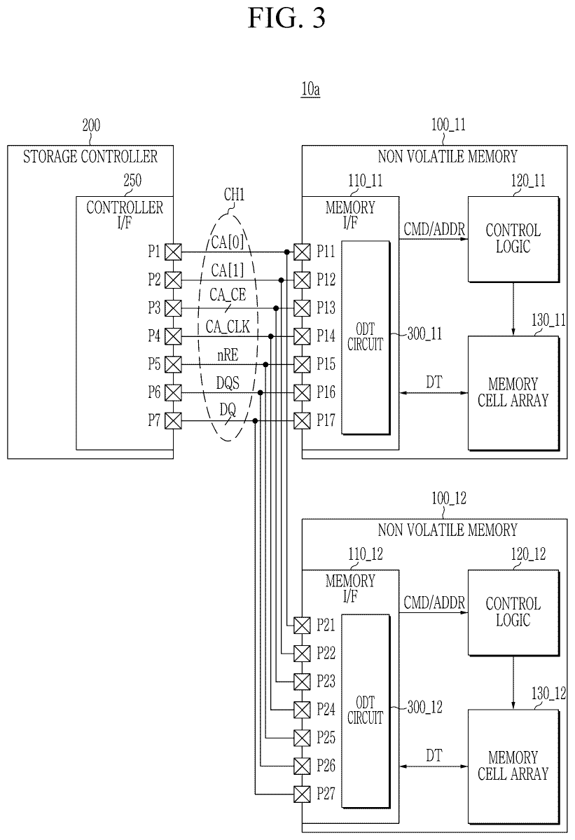

FIG. 3 is a diagram illustrating a storage device according to some embodiments. Specifically, FIG. 3 illustrates a connection relationship between the 1-1 non-volatile memory device 100_11 and the 1-2 non-volatile memory device 100_12 connected to the first channel CH1 of FIG. 2 by way of example.

Referring to FIG. 3, the storage device 10a may include the 1-1 and 1-2 non-volatile memory devices 100_11, 100_12 and a storage controller 200. The storage controller 200 may correspond to the storage controller 200 of FIG. 2. The 1-1 and 1-2 non-volatile memory devices 100_11, 100_12 may correspond to the 1-1 and 1-2 non-volatile memory devices 100_11, 100_12 of FIG. 2, which share the first channel CH1 of FIG. 2 and communicate with the storage controller 200 based on the first channel CH1.

The storage controller 200 may control the overall operation of the storage device 10a. The storage controller 200 may transmit and receive commands, addresses, or data to and from the 1-1 and 1-2 non-volatile memory devices 100_11, 100_12 according to the SCA (Separate Command Address) protocol.

The storage controller 200 may include first to seventh pins P1 to P7 and a controller interface circuit 250. The controller interface circuit 250 may transmit a command address signal CA, a chip enable signal CA_CE, a command address clock signal CA_CLK, a read enable signal nRE, a data strobe signal DQS, and a data signal DQ through first to seventh pins P1 to P7 that are separated from each other and are different from each other. The controller interface circuit 250 may transmit a data signal DQ through a plurality of seventh pins P7, as well as receive a data signal DQ from the 1-1 and 1-2 non-volatile memory devices 100_11, 100_12. Similarly, according to an embodiment, the first and second pins P1 to P2 through which a command address signal CA is input/output may be command address pins, and the plurality of seventh pins P7 through which a data signal DQ is input/output may be data pins.

The 1-1 non-volatile memory device 100_11 may include 1-1 to 1-7 pins P11 to P17, a 1-1 memory interface circuit 110_11, a 1-1 control logic circuit 120_11, and a 1-1 memory cell array 130_11. Each of the 1-1 to 1-7 pins P11 to P17 may correspond to each of the first to seventh pins P1 to P7 of the storage controller 200. Accordingly, the 1-1 memory interface circuit 110_11 may receive a command address signal CA, a chip enable signal CA_CE, a command address clock signal CA_CLK, a read enable signal nRE, a data strobe signal DQS, and a data signal DQ through the 1-1 to 1-7 pins P11 to P17 that are separated from each other and different. The 1-1 memory interface circuit 110_11 may not only receive a data signal DQ but also transmit the data signal DQ to the storage controller 200 through the plurality of 1-7 pins P17.

According to an embodiment, the 1-1 to 1-2 pins P11 to P12 to which a command address signal CA is input/output may be command address pins, and the first non-volatile memory device 100_11 may obtain a command CMD and/or an address ADDR based on the command address signal CA. The plurality of 1-7 pins P17 through which data signal DQ are input/output may be data pins, and the data signal DQ may correspond to data DT programmed or read from the 1-1 non-volatile memory device 100_11.

The 1-1 memory interface circuit 110_11 may include a 1-1 on die termination circuit 300_11. The 1-1 on die termination circuit 300_11 may perform an ODT (On Die Termination) operation of setting termination resistors for the plurality of 1-7 pins P17, which are data pins, based on a command CMD received from the 1-1 to 1-2 pins P11 to P12, and connecting the termination resistors with the plurality of 1-7 pins P17.

The 1-1 on die termination circuit 300_11 may perform various ODT operations, including self-termination operation and non-target termination (NTO) operation, based on a command CMD. The 1-1 on die termination circuit 300_11 may adjust the impedance of the first channel CH1 to which the 1-1 non-volatile memory device 100_11 is connected through an ODT operation and improve the signal quality of the data signal DQ input/output from the first channel CH1.

In the present disclosure, the self-termination operation may be an operation of setting a target termination resistance and connecting it to a data pin of the non-volatile memory device to reduce reflection of a data signal when the non-volatile memory device is a target memory device that inputs and outputs a data signal.

In the present disclosure, the NTO operation may be an operation of setting a non-target termination resistance and connecting it to a data pin of the non-volatile memory device to reduce reflection of a data signal of the target memory device when the non-volatile memory device is a non-target memory device that is connected to a channel where input/output operations of the data signal are performed, but does not itself perform input/output of the data signal. Taking FIG. 3 as an example, while the 1-2 non-volatile memory device 100_12 inputs and outputs a data signal DQ to the first channel CH1 as a target memory device, the 1-1 non-volatile memory device 100_11 may be a non-target memory device. While the 1-2 non-volatile memory device 100_12 inputs and outputs a data signal DQ, a non-target termination resistance that may reduce reflection of the data signal DQ of the 1-2 non-volatile memory device 100_12 may be set and a plurality of 1-7 pins P17 and the non-target termination resistance may be connected.

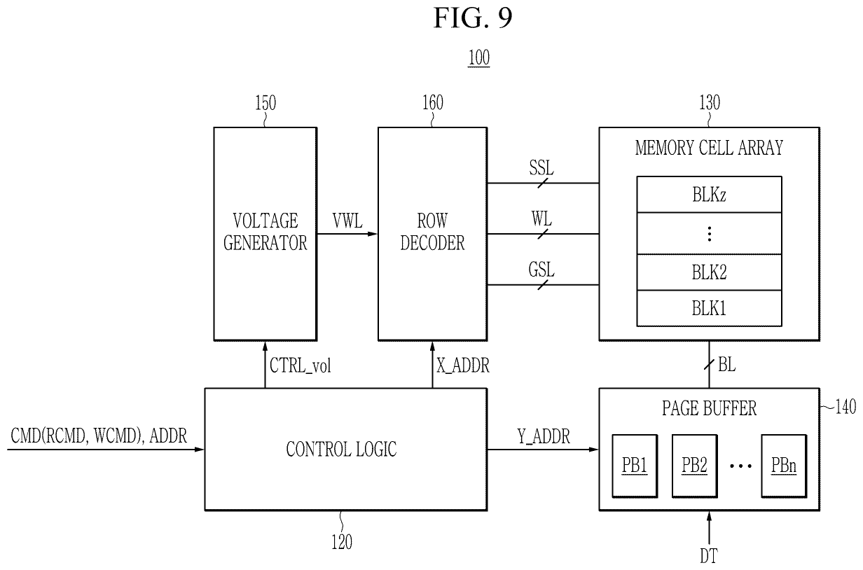

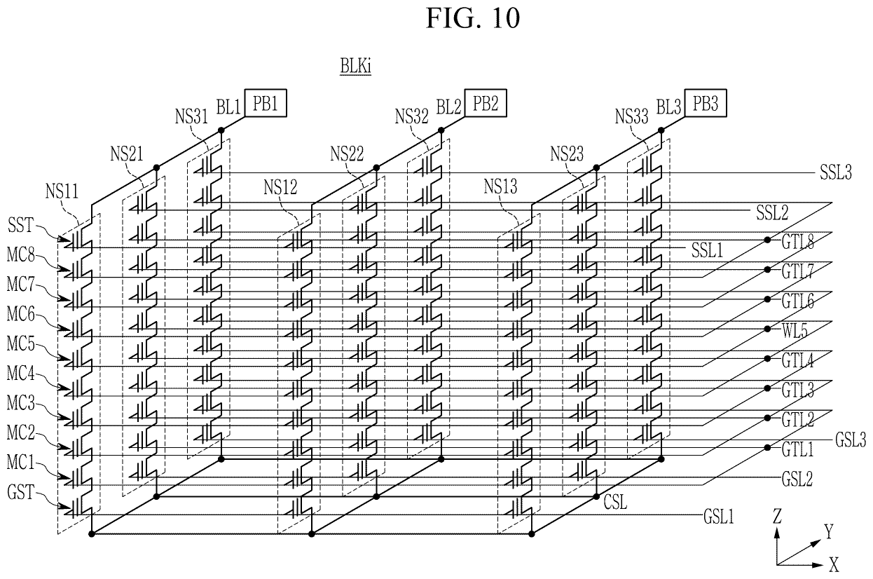

The 1-1 control logic circuit 120_11 may generally control various operations within the 1-1 non-volatile memory device 100_11. The 1-1 control logic circuit 120_11 may output various control signals in response to a command CMD and/or an address ADDR based on a command address signal CA input from the 1-1 to 1-2 pins P11 to P12. The 1-1 control logic circuit 120_11 may control operations for the 1-1 memory cell array 130_11, including program operations, read operations, and erase operations of data DT, based on control signals. A specific description of the 1-1 control logic circuit 120_11 and the 1-1 memory cell array 130_11 is provided later in the description of FIGS. 9 and 10.

The 1-2 non-volatile memory device 100_12 may include 2-1 to 2-7 pins P21 to P27, a 1-2 memory interface circuit 110_12, a 1-2 control logic circuit 120_12, and a 1-2 memory cell array 130_12. Each of the 2-1 to 2-7 pins P21 to P27 may correspond to each of the first to seventh pins P1 to P7 of the storage controller 200. Accordingly, the 1-2 memory interface circuit 110_12 may receive a command address signal CA, a chip enable signal CA_CE, a command address clock signal CA_CLK, a read enable signal nRE, a data strobe signal DQS, and a data signal DQ through the 2-1 to 2-7 pins P21 to P27 which are separated from each other and different. The 1-2 memory interface circuit 110_12 may not only receive a data signal DQ but also transmit the data signal DQ to the storage controller 200 through the plurality of 2-7 pins P27.

According to an embodiment, the 2-1 to 2 -2 pins P21 to P22 to which a command address signal CA is input/output may be command address pins, and the 1-2 non-volatile memory device 100_12 may obtain a command CMD and/or an address ADDR based on the command address signal CA. The plurality of 2-7 pins P27 through which data signal DQ are input/output may be data pins, and the data signal DQ may correspond to data DT programmed or read from the 1-2 non-volatile memory device 100_12.

The 1-2 memory interface circuit 110_12 may include a 1-2 on die termination circuit 300_12. The 1-2 on die termination circuit 300_12 may perform an ODT operation of setting termination resistors for a plurality of 2-7 pins P27, which are data pins, based on a command CMD received from the 2-1 to 2 -2 pins P21 to P22, and connecting the termination resistors with the plurality of 2-7 pins P27.

The 1-2 on die termination circuit 300_12 may perform various ODT operations, including self-termination operation and NTO operation, based on a command CMD. The 1-2 on die termination circuit 300_12 may adjust the impedance of the first channel CH1 connected to the 1-2 non-volatile memory device 100_12 through an ODT operation and improve the signal quality of the data signal DQ input/output from the first channel CH1.

The 1-2 control logic circuit 120_12 may generally control various operations within the 1-2 non-volatile memory device 100_12. The 1-2 control logic circuit 120_12 may output various control signals in response to a command CMD and/or an address ADDR based on a command address signal CA input from the 2-1 to 2 -2 pins P21 to P22. The 1-2 control logic circuit 120_12 may control operations for the 1-2 memory cell array 130_12, including program operations, read operations, and erase operations of data DT, based on control signals. A specific description of the 1-2 control logic circuit 120_12 and the 1-2 memory cell array 130_12 is provided later in the description of FIGS. 9 and 10.

The chip enable signal CA_CE may be provided to the 1-1 non-volatile memory device 100_11 through the third pin P3 and the 1-3 pin P13, and may be provided to the 1-2 non-volatile memory device 100_12 through the third pin P3 and the 2-3 pin P23. The chip enable signal CA_CE may be a signal to select a non-volatile memory device to which a command CMD and address ADDR will be provided via the command/address line. For example, the chip enable signal CA_CE may be maintained at a logic high level and transitioned to a logic low level when a non-volatile memory device is selected, and a non-volatile memory device receiving the chip enable signal CA_CE at a logic low level may receive a command CMD and an address ADDR from a command address signal CA.

In FIG. 3, the storage controller 200 provides a chip enable signal CA_CE to the 1-1 and 1-2 non-volatile memory devices 100_11, 100_12 through a third pin P3, but according to an embodiment, the storage controller 200 may provide the chip enable signal CA_CE to the 1-1 non-volatile memory device 100_11 and the 1-2 non-volatile memory device 100_12 through separate pins, respectively.

The command address clock signal CA_CLK may remain in a static state (e.g., logic high level or logic low level) and toggle between logic high level and logic low level during a specific period. For example, the command address clock signal CA_CLK may be toggled during the period in which the command address signal CA is transmitted.

The 1-1 and 1-2 memory interface circuits 110_11, 110_12 provide a command address signal CA based on the toggle timings of a command address clock signal CA_CLK, and may obtain a command CMD and an address ADDR from the command address signal CA. Command CMD and addresses ADDR may be provided in the form of CA packets. According to the embodiment, the command CMD may include a read command, a write command, a select chip enable command, a select chip terminate command, a select chip pause command, an NTO enable command, and an NTO disable command.

In the data signal DQ output operation of the 1-1 and 1-2 non-volatile memory devices 100_11, 100_12, each of the 1-1 and 1-2 memory interface circuits 110_11, 110_12 may receive a read enable signal nRE that toggles through the 1-5 and 2-5 pins P15, P25 before outputting the data signal DQ. The 1-1 and 1-2 memory interface circuits 110_11, 110_12 may generate a data strobe signal DQS that toggles based on the toggling of the read enable signal nRE. For example, the 1-1 and 1-2 memory interface circuits 110_11, 110_12 may generate a data strobe signal DQS that starts toggling after a predetermined delay based on the toggling start time of the read enable signal nRE. The 1-1 and 1-2 memory interface circuits 110_11, 110_12 may output a data signal DQ for data DT based on the toggle timing of the data strobe signal DQS. Accordingly, the data signal DQ may be transmitted to the storage controller 200 aligned with the toggle timing of the data strobe signal DQS.

In the data signal DQ input operation of the 1-1 and 1-2 non-volatile memory devices 100_11, 100_12, the controller interface circuit 250 may generate a toggling data strobe signal DQS. For example, the data strobe signal DQS may remain in a fixed state (e.g., high level or low level) and then start toggling before the data signal DQ is transmitted. The controller interface circuit 250 may transmit a data signal DQ for data DT to the 1-1 and 1-2 non-volatile memory devices 100_11, 100_12 based on the toggle timings of the data strobe signal DQS. For example, the data signal DQ may be transmitted aligned with the edge timing of the data strobe signal DQS.

In FIG. 3, only the connection relationship between the 1-1 and 1-2 non-volatile memory devices 100_11, 100_12 and the first channel CH1 is illustrated, but is not limited thereto, and the description in FIG. 3 may be applied to a plurality of non-volatile memory devices connected to the same channel.

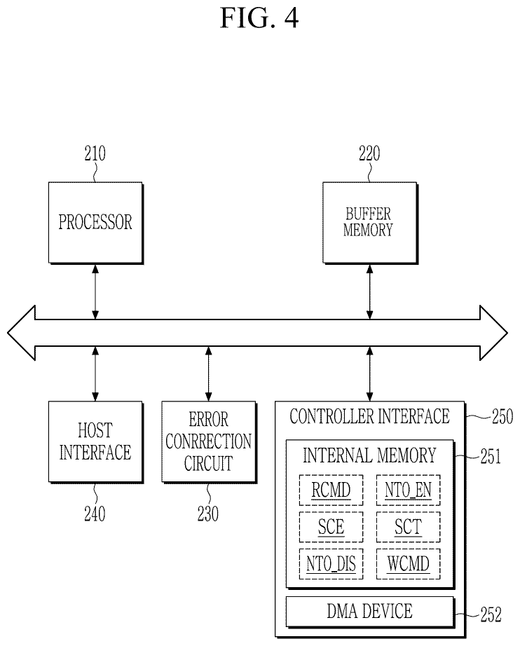

FIG. 4 is a block diagram illustrating a storage controller according to some embodiments.

Referring to FIGS. 1, 2, and 4, the storage controller 200 may control the overall operation of the storage device 10.

In some embodiments, the storage controller 200 may execute firmware when power is applied to the storage device 10. The firmware may include a host interface layer that controls communication with a host device 20, a flash translation layer that provides an interface between the host device 20 and the plurality of non-volatile memory devices 100_11 to 100_mn so that the plurality of non-volatile memory devices 100_11 to 100_mn are used efficiently, and a memory interface layer that controls communication with the plurality of non-volatile memory devices 100_11 to 100_mn. According to some embodiments, the flash translation layer may perform an address mapping operation, a garbage collection operation, a wear leveling operation, a read reclaim operation, etc., which translates a logical address of a host device 20 into a physical address of a plurality of non-volatile memory devices 100_11 to 100_mn as a memory management module.

According to some embodiments, the storage controller 200 may control a plurality of non-volatile memory devices 100_11 to 100_mn to perform a program operation, a read operation, or an erase operation, etc., in response to an operation request RQ of the host device 20. The storage controller 200 may provide program commands, addresses, and data to a plurality of non-volatile memory devices 100_11 to 100_mn during program operation. The storage controller 200 may provide read commands and addresses to the plurality of non-volatile memory devices 100_11 to 100_mn during a read operation. The storage controller 200 may provide an erase command and address to the plurality of non-volatile memory devices 100_11 to 100_mn during an erase operation.

In an embodiment, the storage controller 200 may include a processor 210, a buffer memory 220, an error correction circuit 230, a host interface circuit 240, and a controller interface circuit 250.

The processor 210 may control the overall operation of the storage controller 200. The processor 210 may generate commands according to an operation request RQ of the host device 20. In some embodiments, the processor 210 may generate a read command RCMD in response to a read request from the host device 20 and may generate a program command WCMD in response to a write request from the host device 20.

The processor 210 may generate an NTO enable command NTO_EN to enable an NTO operation of an on die termination circuit included in a plurality of non-volatile memory devices 100_11 to 100_mn, and may generate an NTO disable command NTO_DIS to disable the NTO operation of the on die termination circuit.

According to some embodiments, the processor 210 may generate an NTO enable command NTO_EN or an NTO disable command NTO_DIS for all of the plurality of non-volatile memory devices 100_11 to 100_mn, or may generate an NTO enable command NTO_EN or an NTO disable command NTO_DIS for one of the plurality of non-volatile memory devices 100_11 to 100_mn.

The processor 210 may generate a select chip enable command SCE, a select chip terminate command SCT, a select chip pause command, etc. related to data input/output operations of a plurality of non-volatile memory devices 100_11 to 100_mn.

The select chip enable command SCE is a command for selecting a non-volatile memory device performing data input/output from among a plurality of non-volatile memory devices 100_11 to 100_mn, and a non-volatile memory device receiving the select chip enable command SCE may perform a self-termination operation and a data input/output operation as a target memory device. The select chip terminate command SCT is a command that terminates a data input/output operation of a non-volatile memory device selected by the select chip enable command SCE, and a non-volatile memory device that receives the select chip terminate command SCT may not perform a self-termination operation and a data input/output operation.

According to an embodiment, the processor 210 may generate a select chip enable command SCE to disable the NTO operation and enable the self-termination operation of the selected non-volatile memory device. According to an embodiment, the processor 210 may generate a select chip terminate command SCT corresponding to a select chip enable command SCE to disable a self-termination operation of the selected non-volatile memory device and enable an NTO operation. Although not illustrated in the drawing, the processor 210 may generate a select chip pause command corresponding to the select chip enable command SCE to disable the self-termination operation of the selected non-volatile memory device and disable the NTO operation.

When controlling data input/output operations for a plurality of non-volatile memory devices connected to one channel, the processor 210 may control NTO operations and self-termination operations for the plurality of non-volatile memory devices based on a sequence of an NTO enable command NTO_EN, an NTO disable command NTO_DIS, a select chip enable command SCE, and a select chip terminate command SCT.

The processor 210 may provide the generated commands to the controller interface circuit 250. The processor 210 may control the controller interface circuit 250 to provide commands to a plurality of non-volatile memory devices 100_11 to 100_mn.

Buffer memory 220 may be used as cache memory or operating memory of the storage controller 200.

According to some embodiments, the buffer memory 220 may temporarily store data DT provided from the host device 20 or temporarily store data DT read from the plurality of non-volatile memory devices 100_11 to 100_mn. In an embodiment, the buffer memory 220 may be a dynamic random access memory DRAM or a static random access memory SRAM. In an embodiment, the buffer memory 220 may be located within the storage controller 200 or may be located outside the storage controller 200.

In some embodiments, the error correction circuit 230 may perform an encoding operation to generate parity data for data DT received from the host device 20. Encoded data may be provided to the plurality of non-volatile memory devices 100_11 to 100_mn through a controller interface circuit 250. The error correction circuit 230 may perform a decoding operation on data read from the plurality of non-volatile memory devices 100_11 to 100_mn. The error correction circuit 230 may correct error bits included in data read from the plurality of non-volatile memory devices 100_11 to 100_mn by performing a decoding operation. The error correction circuit 230 may provide decoded data to the host device 20 through the host interface circuit 240.

The host interface circuit 240 may communicate with the host device 20. The host interface circuit 240 may receive data DT from the host device 20 or provide data DT to the host device 20.

The controller interface circuit 250 may communicate with the plurality of non-volatile memory devices 100_11 to 100_mn. The controller interface circuit 250 may provide data to the plurality of non-volatile memory devices 100_11 to 100_mn or receive data from the plurality of non-volatile memory devices 100_11 to 100_mn.

According to some embodiments, the controller interface circuit 250 may include internal memory 251 and a Direct Memory Access DMA device 252.

The internal memory 251 may store commands generated by the processor 210. Under the control of the processor 210, commands stored in the internal memory 251 may be provided to the plurality of non-volatile memory devices 100_11 to 100_mn. In some embodiments, the internal memory 251 may be DRAM or SRAM. The DMA device 1362 may transmit and receive data from the plurality of non-volatile memory devices 100_11 to 100_mn.

Although it is illustrated in FIG. 4 that commands generated by the processor 210 are stored as a command queue in the internal memory 251 of the controller interface circuit 250, this is not limited thereto, and according to an embodiment, commands generated by the processor 210 may be stored as a command queue in the buffer memory 220.

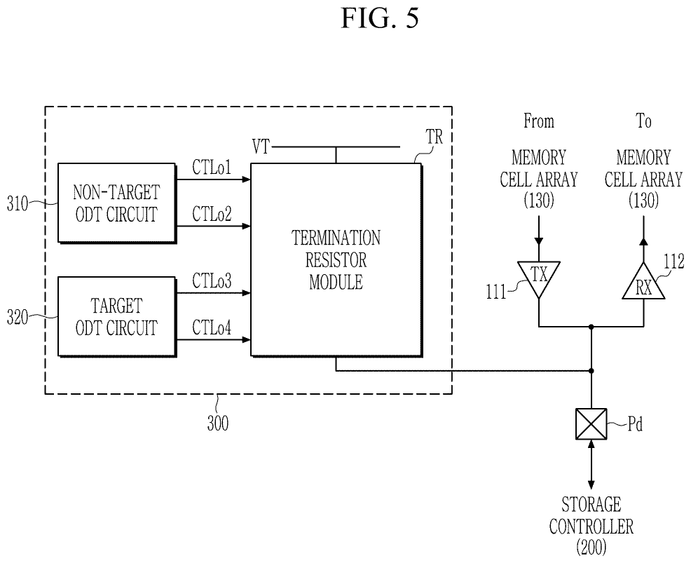

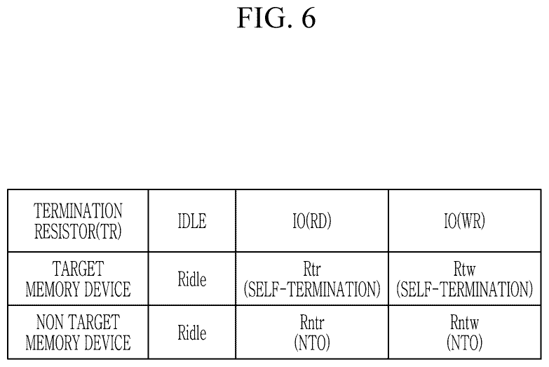

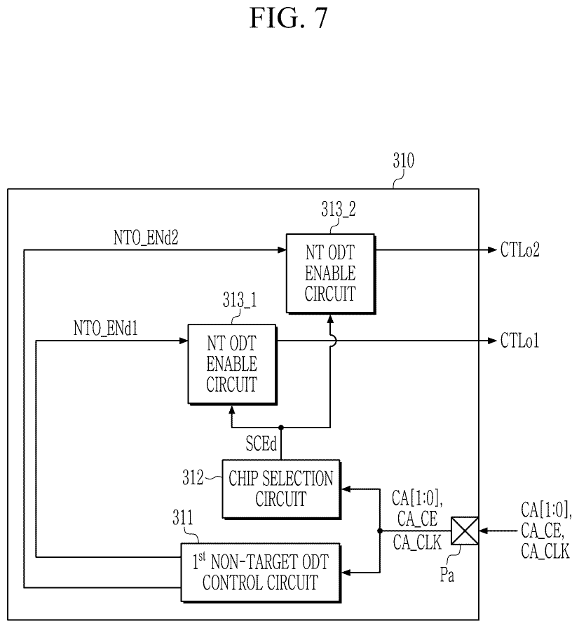

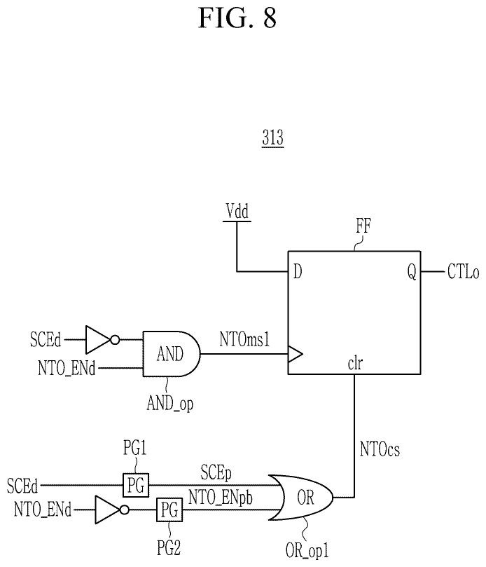

FIG. 5 is a block diagram and FIG. 6 is a table illustrating on die termination circuits according to some embodiments. FIG. 7 is a block diagram illustrating a non-target ODT circuit according to some embodiments. FIG. 8 is a block diagram illustrating a non-target ODT enable circuit according to some embodiments.

The on die termination circuit 300 of FIG. 5 corresponds to the 1-1 and 1-2 on die termination circuits 300_11, 300_12 of FIG. 3, the memory cell array 130 of FIG. 5 corresponds to the 1-1 and 1-2 memory cell arrays 130_11, 130_12 of FIG. 3, and the data pin Pd of FIG. 5 may correspond to the 1-7 and 2-7 pins P17, P27 of FIG. 3. The description of each of the 1-1 and 1-2 on die termination circuits 300_11, 300_12, the 1-1 and 1-2 memory cell arrays 130_11, 130_12, and the 1-7 and 2-7 pins P17, P27 may be applied to the on die termination circuit 300, the memory cell array 130, and the data pin Pd, respectively. According to some embodiments, the on die termination circuit 300 may be included in a memory interface circuit within a non-volatile memory device.

Referring to FIGS. 3 to 8, the storage controller 200 may exchange data DT with the memory cell array 130 through a data pin Pd and a transmitter 111 and a receiver 112 connected to the data pin Pd.

The on die termination circuit 300 may include a termination resistor module TR, a non-target ODT circuit 310, and a target ODT circuit 320.

A termination resistor module TR may be connected in series between the power line providing the termination voltage VT and the data pin Pd. The termination resistor module TR may operate as a termination resistor connected to the data pin Pd. One terminal of the termination resistor module TR is connected to a power line providing a termination voltage VT, and the other terminal of the termination resistor module TR may be connected between a transmitter 111 connected to a memory cell array 130 and a data pin Pd, or between a receiver 112 connected to a memory cell array 130 and a data pin Pd.

According to an embodiment, the terminal resistor module TR may include a plurality of resistors and a plurality of switches. The terminal resistor module TR may receive ODT control signals CTLo1 to CTLo4 generated from the non-target ODT circuit 310 and the target ODT circuit 320. The on die termination circuit 300 performs an ODT operation based on an ODT control signal CTLo1 to CTLo4 to set a resistance value for the termination resistor of the termination resistor module TR and connect it to a data pin Pd.

Referring to FIG. 6 as an example, when the non-volatile memory device is in a standby state with the ODT operation disabled, the termination resistor of the termination resistor module TR may be an idle resistance Ridle. In some embodiments, when the non-volatile memory device is in a standby state, the termination resistor module TR may be floated so that no current flows through the termination resistor module TR. When data DT is read from a memory cell array 130 and a data signal DQ is output to a channel in a non-volatile memory device, the target memory device may enable a self-termination operation and set the termination resistor of the termination resistor module TR to a read target termination resistance Rtr based on the third and fourth ODT control signals CTLo3, CTLo4. The non-target memory device may enable the NTO operation and set the termination resistor of the termination resistor module TR to a read non-target termination resistance Rntr based on the first and second ODT control signals CTLo1, CTLo2.

When data DT is programmed in the memory cell array 130 and a data signal DQ is input to a non-volatile memory device from a channel, the target memory device may enable a self-termination operation and set the termination resistor of the termination resistor module TR to a write target termination resistance Rtw based on the third and fourth ODT control signals CTLo3, CTLo4. The non-target memory device may enable the NTO operation and set the termination resistor of the termination resistor module TR to a write non-target termination resistance Rntw based on the first and second ODT control signals CTLo1, CTLo2.

In some embodiments, the write non-target termination resistance Rntw may be greater than the write target termination resistance Rtw, and the read non-target termination resistance Rntr may be greater than the read target termination resistance Rtr. In some embodiments, the idle resistance Ridle, the read target termination resistance Rtw, the read target termination resistance Rtr, and the read non-target termination resistance Rntw may be set in a Set Feature operation of the storage device 10a.

The non-target ODT circuit 310 may include a first non-target ODT control circuit 311, a chip selection circuit 312, and first and second NTO enable circuits 313_1, 313_2. The non-target ODT circuit 310 receives a command address signal CA, a chip enable signal CA_CE, and a command address clock signal CA_CLK from the storage controller 200, and generates first and second ODT control signals CTLo1, CTLo2 based on the command address signal CA and the chip enable signal CA_CE to control the NTO operation of the on die termination circuit 300. For example, the non-target ODT circuit 310 may enable the NTO operation by transitioning at least one of the first and second ODT control signals CTLo1, CTLo2 to a logic high level, and may disable the NTO operation by transitioning the first and second ODT control signals CTLo1, CTLo2 to a logic low level.

The first non-target ODT control circuit 311 receives a command address signal CA, a chip enable signal CA_CE, and a command address clock signal CA_CLK from the a-th pin Pa, decodes a command CMD and an address ADDR in the form of a CA packet for the command address signal CA, and may generate NTO enable data NTO_ENd1, NTO_ENd2. The a-th pin Pa may correspond to the 1-1 to 1_4 and 2_1 to 2_4 pins (P11 to P14, P21 to P24) of FIG. 3.

The first non-target ODT control circuit 311 may transition the level of at least one NTO enable data NTO_ENd1, NTO_ENd2 when receiving a command for an NTO operation of the non-volatile memory device. For example, the first non-target ODT control circuit 311 may transition at least one of the first and second NTO enable data NTO_ENd1, NTO_ENd2 to a logic high level in response to receiving an NTO enable command NTO_EN for the non-volatile memory device. Additionally, the first non-target ODT control circuit 311 may transition the first and second NTO enable data NTO_ENd1, NTO_ENd2 to a logic low level in response to receiving an NTO disable command NTO_DIS for the corresponding non-volatile memory device.

The chip selection circuit 312 may receive a command address signal CA, a chip enable signal CA_CE, and a command address clock signal CA_CLK from the a-th pin Pa, and decode a command CMD and an address ADDR in the form of a CA packet for the command address signal CA, thereby generating a select chip enable data SCEd. The above CA packet may include an NTO packet for enabling or disabling the NTO operation of the on die termination circuit 300.

The chip selection circuit 312 may transition the level of the select chip enable data SCEd when receiving a command related to a data input/output operation of the non-volatile memory device. For example, the chip selection circuit 312 may transition the select chip enable data SCEd to a logic high level in response to receiving a select chip enable command SCE for the corresponding non-volatile memory device. Additionally, the chip selection circuit 312 may transition the select chip enable data SCEd to a logic low level in response to receiving a select chip terminate command SCT for the corresponding non-volatile memory device. According to an embodiment, the chip selection circuit 312 may transition the select chip enable data SCEd to a logic low level in response to receiving a select chip pause command for the corresponding non-volatile memory device.

The first NTO enable circuit 313_1 may receive the first NTO enable data NTO_ENd1 and the select chip enable data SCEd, and output the first ODT control signal CTLo1 based on a logical operation on the first NTO enable data NTO_ENd1 and the select chip enable data SCEd. The second NTO enable circuit 313_2 may receive second NTO enable data NTO_ENd2 and select chip enable data SCEd, and output a second ODT control signal CTLo2 based on a logical operation on the second NTO enable data NTO_ENd2 and select chip enable data SCEd.

In FIG. 8, the NTO enable circuit 313 illustrates an exemplary circuit for a first NTO enable circuit 313_1 and a second NTO enable circuit 313_2, and the NTO enable data NTO_ENd may correspond to the first and second NTO enable data NTO_ENd1, NTO_ENd2, and the ODT control signal CTLo may correspond to the first and second ODT control signals CTLo1, CTLo2. For ease of the explanation below, the description of the first NTO enable circuit 313_1 and the second NTO enable circuit 313_2 is replaced with the description of the NTO enable circuit 313.

The NTO enable circuit 313 may include a flip-flop FF, a AND operator AND_op, a first OR operator OR_op1, and first and second pulse generators PG1, PG2.

The flip-flop FF may receive a high-voltage power supply voltage Vdd as an input signal, receive a first NTO merge signal NTOms1, which is a result value of a AND operator AND_op, as a clock signal, and output an ODT control signal CTLo. The flip-flop FF may receive the NTO clear signal NTOcs, which is the result value of the first OR operator OR_op1, as a reset signal and reset the ODT control signal CTLo.

In some embodiments, the flip-flop FF may output and latch an ODT control signal CTLo of a logic high level in response to a rising edge of the first NTO merge signal NTOms1. In some embodiments, the flip-flop FF may reset the ODT control signal CTLo in response to the NTO clear signal NTOcs transitioning to a logic high level.

The AND operator AND_op may perform a AND operation on the inverted data of the NTO enable data NTO_ENd and the select chip enable data SCEd to generate a first NTO merge signal NTOms1.

The first OR operator OR_op1 may perform an OR operation on the select chip enable pulse signal SCEp for the select chip enable data SCEd and the inverted NTO enable pulse signal NTO_ENpb for the NTO enable data NTO_ENd to generate an NTO clear signal NTOcs. The select chip enable pulse signal SCEp may be a pulse signal generated by the first pulse generator PG1 based on the rising edge of the select chip enable data SCEd. The inverted NTO enable pulse signal NTO_ENpb may be a pulse signal generated by the second pulse generator PG2 based on the falling edge of the NTO enable data NTO_ENd.

The NTO enable circuit 313 may control the NTO operation through the operations of the above-described flip-flop FF, the AND operator AND_op, the first OR operator OR_op1, and the first and second pulse generators PG1, PG2.

For example, when the NTO enable command NTO_EN is input and the NTO enable data NTO_ENd is maintained at a logic high level and the select chip enable command SCE is input and the select chip enable data SCEd transitions to a logic high level, the NTO clear signal NTOcs transitions to a logic high level so that the ODT control signal CTLo may be reset to a logic low level. In addition, when the NTO enable command NTO_EN is input and the NTO enable data NTO_ENd is maintained at a logic high level and the select chip terminate command SCT is input and the select chip enable data SCEd transitions to a logic low level, the first NTO merge signal NTOms1 transitions to a logic high level and an ODT control signal CTLo at a logic high level may be output in response to the rising edge of the first NTO merge signal NTOms1.

The target ODT circuit 320 receives a command address signal CA, a chip enable signal CA_CE, and a command address clock signal CA_CLK from the storage controller 200, and generates third and fourth ODT control signals CTLo3, CTLo4 based on the command address signal CA and the chip enable signal CA_CE to control the self-termination operation of the on die termination circuit 300.

For example, the target ODT circuit 320 may receive a select chip enable command SCE and transition at least one of the third and fourth ODT control signals CTLo3, CTLo4 to a logic high level to enable a self-termination operation. Likewise, the target ODT circuit 320 may receive a select chip terminate command SCT corresponding to a select chip enable command SCE and disable the self-termination operation by transitioning the third and fourth ODT control signals CTLo3, CTLo4 to a logic low level.

The on die termination circuit 300 may control the NTO operation based on a select chip enable command SCE or a select chip terminate command SCT related to a data input/output operation through a non-target ODT circuit 310.

Since the SCA protocol prohibits non-volatile memory devices from performing NTO operations and data I/O operations simultaneously, NTO operations must be disabled before data I/O operations on non-volatile memory devices. The storage device 10a may control the NTO operation and improve the data input/output efficiency of the storage device 10a by issuing a select chip enable command SCE or a select chip terminate command SCT without additional issuance of an NTO enable command NTO_EN and an NTO disable command NTO_DIS through a non-target ODT circuit 310.

FIG. 9 is a block diagram illustrating a non-volatile memory device according to some embodiments. FIG. 10 is a schematic for explaining a three-dimensional structure of a memory cell array according to some embodiments. Specifically, the non-volatile memory device 100 of FIG. 9 illustrates configurations of a plurality of non-volatile memory devices 100_11 to 100_mn of FIGS. 2 and 3 by way of example. The description of the non-volatile memory device 100 of FIG. 9 may be applied to a plurality of non-volatile memory devices 100_11 to 100_mn, and for ease of description below, the description of the plurality of non-volatile memory devices 100_11 to 100_mn of FIGS. 2 and 3 is replaced with the description of the non-volatile memory device 100 of FIG. 9.

Referring to FIGS. 9 and 10, a non-volatile memory device 100 may include a control logic circuit 120, a memory cell array 130, a page buffer circuit 140, a voltage generator 150, and a row decoder 160. Although not illustrated in FIG. 9, the non-volatile memory device 100 may further include a memory interface circuit 110 including an on die termination circuit 300, and may further include column logic, a pre-decoder, a temperature sensor, a command decoder, an address decoder, and the like.

The control logic circuit 120 may control various operations within the non-volatile memory device 100. The control logic circuit 120 receives a command CMD and/or an address ADDR including a read command RCMD or a program command WCMD from the first to second pins P11 to P12 or the second to second pins P21 to P22 of FIG. 3, and may output various control signals in response to the command CMD and/or the address ADDR. For example, the control logic circuit 120 may output a voltage control signal CTRL_vol, a row address X-ADDR, and a column address Y-ADDR.

The memory cell array 130 may include a plurality of memory blocks BLK1 to BLKz (z is a positive integer), and each of the plurality of memory blocks BLK1 to BLKz may include a plurality of memory cells. The memory cell array 130 may be connected to a page buffer circuit 140 through bit lines BL and may be connected to a row decoder 160 through word lines WL, string select lines SSL, and ground select lines GSL.

According to some embodiments, the memory cell array 130 may include a three-dimensional memory cell array, and the three-dimensional memory cell array may include a plurality of NAND strings. Each NAND string may include memory cells each connected to word lines stacked vertically on the substrate. According to some embodiments, the memory cell array 130 may include a two-dimensional memory cell array, and the two-dimensional memory cell array may include a plurality of NAND strings arranged along the row and column directions.

Referring to FIG. 10 together, each of the plurality of memory blocks BLK1 to BLKz may be expressed as an equivalent circuit as illustrated. The memory block BLKi illustrated in FIG. 10 represents a three-dimensional memory block formed in a three-dimensional structure on a substrate. For example, a plurality of memory NAND strings included in a memory block BLKi may be formed in a direction perpendicular to the substrate.

A memory block BLKi may include a plurality of memory NAND strings NS11 to NS33 connected between a plurality of bit lines BL1, BL2, BL3 and a common source line CSL. Each of the plurality of memory NAND strings NS11 to NS33 may include a string select transistor SST, a plurality of memory cells MC1, MC2, . . . , MC8, and a ground select transistor GST. In FIG. 10, each of the plurality of memory NAND strings NS11 to NS33 is illustrated as including eight memory cells MC1, MC2, . . . , MC8, but is not necessarily limited thereto.

The string select transistors SST may be connected to corresponding string select lines SSL1, SSL2, SSL3. A plurality of memory cells MC1, MC2, . . . , MC8 may be respectively connected to corresponding gate lines GTL1, GTL2, . . . , GTL8. Gate lines GTL1, GTL2, . . . , GTL8 may correspond to word lines, and some of the gate lines GTL1, GTL2, . . . , GTL8 may correspond to dummy word lines. The ground select transistor GST may be connected to the corresponding ground select line GSL1, GSL2, GSL3. The string select transistor SST may be connected to the corresponding bit lines BL1, BL2, BL3, and the ground select transistor GST may be connected to the common source line CSL. Each bit line BL1, BL2, BL3 may be connected to a corresponding page buffer PB1, PB2, PB3. Each page buffer PB1, PB2, PB3 may be a page buffer included in the page buffer circuit 140 of FIG. 9.

Word lines of the same height (e.g., WL1) are commonly connected, and ground select lines GSL1, GSL2, GSL3 and string select lines SSL1, SSL2, SSL3 may be separated, respectively. In FIG. 10, a memory block BLK is illustrated as being connected to eight gate lines GTL1, GTL2, . . . , GTL8 and three bit lines BL1, BL2, BL3, but is not necessarily limited thereto.

The page buffer circuit 140 may include a plurality of page buffers PB1 to PBn (n is an integer greater than or equal to 3), and the plurality of page buffers PB1 to PBn may be respectively connected to memory cells through a plurality of bit lines BL. The page buffer circuit 140 may select at least one bit line among a plurality of bit lines BL in response to a column address Y-ADDR.

The page buffer circuit 140 may operate as a write driver or a sense amplifier depending on the operating mode. For example, during a program operation, the page buffer circuit 140 may apply a bit line voltage corresponding to data DT to be programmed to a selected bit line. During a read operation, the page buffer circuit 140 may detect data DT stored in a memory cell by detecting the current or voltage of the selected bit line. According to some embodiments, data DT may be input/output as a data signal DQ through a page buffer circuit 140 and a data pin of a memory interface circuit.

The voltage generator 150 may generate various types of voltages for performing program, read, and erase operations based on a voltage control signal CTRL_vol. For example, the voltage generator 150 may generate a program voltage, a read voltage, a program verify voltage, an erase voltage, etc., or a bit line voltage, etc., as a word line voltage VWL.

A row decoder 160 may select one of a plurality of word lines WL and one of a plurality of string select lines SSL in response to a row address X-ADDR. For example, during a program operation, the row decoder 160 may apply a program voltage and a program verification voltage to a selected word line, and during a read operation, it may apply a read voltage to a selected word line.

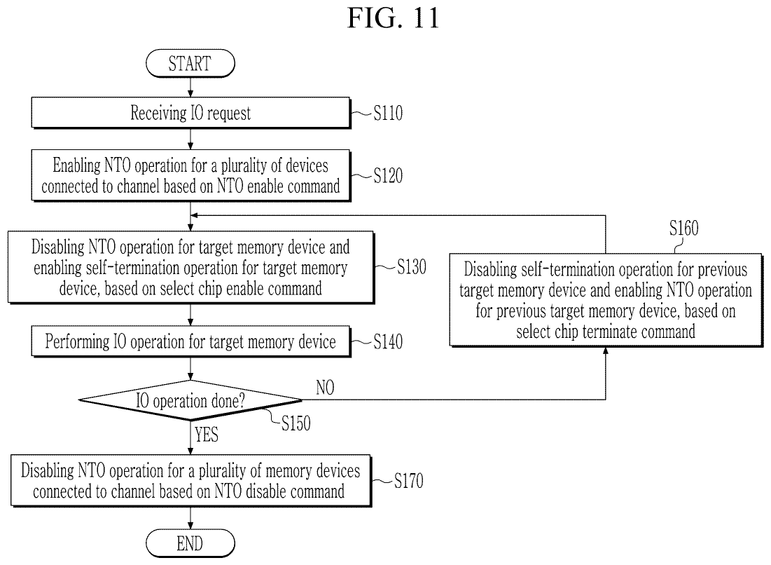

FIG. 11 is a flowchart illustrating a method of operating a storage device according to some embodiments.

Referring to FIGS. 1 to 8 and 11, the storage controller 200 receives an operation request RQ for data input/output from the host device 20 (S110).

Taking FIG. 3 as an example, the storage controller 200 may receive an operation request RQ such as a read request or a write request for the 1-1 and 1-2 non-volatile memory devices 100_11, 100_12 from the host device 20. The storage controller 200 may provide a command CMD, such as a read command RCMD or a program command WCMD, to the 1-1 and 1-2 non-volatile memory devices 100_11, 100_12 according to an operation request RQ.

According to some embodiments, the 1-1 and 1-2 non-volatile memory devices 100_11, 100_12 sharing the first channel CH1 may receive a command CMD and perform a read operation or a program operation in a way interleaving manner.

The storage controller 200 enables NTO operation for the plurality of non-volatile memory devices connected to the channel based on the NTO enable command NTO_EN (S120).

The storage controller 200 may generate an NTO enable command NTO_EN for a plurality of non-volatile memory devices sharing a channel, and provide the NTO enable command NTO_EN to the plurality of non-volatile memory devices to enable an NTO operation for the plurality of non-volatile memory devices.

A plurality of non-volatile memory devices receive an NTO enable command NTO_EN, and an on die termination circuit 300 of each of the plurality of non-volatile memory devices may generate at least one NTO enable data NTO_ENd of a logic high level. Since the plurality of non-volatile memory devices have not received a select chip enable command SCE from the storage controller 200, the on die termination circuit 300 of the plurality of non-volatile memory devices may enable an NTO operation based on the rising edge of the first NTO merge signal NTOms1, which is a logical AND operation value of the inverted data of the select chip enable data SCEd and the NTO enable data NTO_ENd.

Taking FIG. 3 as an example, the storage controller 200 may generate an NTO enable command NTO_EN for all of the 1-1 and 1-2 non-volatile memory devices 100_11, 100_12 connected to the first channel CH1. The generated NTO enable command NTO_EN may be provided to the 1-1 and 1-2 non-volatile memory devices 100_11, 100_12 through the first and second pins P1 to P2. The 1-1 and 1-2 non-volatile memory devices 100_11, 100_12 receive an NTO enable command NTO_EN through a command address signal CA, and each of the first and second on die termination circuits 300_11, 300_12 may generate at least one NTO enable data NTO_ENd of a logic high level. Since the 1-1 and 1-2 non-volatile memory devices 100_11, 100_12 have not received a select chip enable command SCE from the storage controller 200, the first and second on die termination circuits 300_11, 300_12 may enable an NTO operation based on the rising edge of the first NTO merge signal NTOms1, which is a logical AND operation value of the inverted data of the select chip enable data SCEd and the NTO enable data NTO_ENd.

The storage controller 200 disables the NTO operation for the target memory device and enables the self-termination operation for the target memory device based on the select chip enable command SCE (S130).

A storage controller 200 may generate a select chip enable command SCE for a target memory device among a plurality of non-volatile memory devices, and provide the select chip enable command SCE to the target memory device so that the target memory device disables an NTO operation and enables a self-termination operation.

Among a plurality of non-volatile memory devices, a target memory device receives a select chip enable command SCE, and an on die termination circuit 300 of the target memory device may transition select chip enable data SCEd of the target memory device to a logic high level.

The on die termination circuit 300 of the target memory device may disable the NTO operation based on an NTO clear signal NTOcs, which is a logical OR operation value of a selection enable pulse signal SCEp for the select chip enable data SCEd and an inverted NTO enable pulse signal NTO_ENpb for the NTO enable data NTO_ENd. Additionally, the on die termination circuit 300 of the target memory device may enable self-termination operation based on a select chip enable command SCE.

Taking FIG. 3 as an example, a storage controller 200 may generate a select chip enable command SCE for a 1-1 non-volatile memory device 100_11 among the 1-1 and 1-2 non-volatile memory devices 100_11, 100_12, and the 1-1 non-volatile memory device 100_11 is a target memory device. The generated select chip enable command SCE may be provided to the 1-1 non-volatile memory device 100_11 through the first and second pins P1 to P2 and the 1-1 to 1-2 pins P11 to P12. The 1-1 non-volatile memory device 100_11 receives a select chip enable command SCE through a command address signal CA, and the 1-1 on die termination circuit 300_11 may transition the select chip enable data SCEd to a logic high level. The 1-1 on die termination circuit 300_11 may disable the NTO operation based on an NTO clear signal NTOcs, which is a logical OR operation value of a selection enable pulse signal SCEp for the select chip enable data SCEd and an inverted NTO enable pulse signal NTO_ENpb for the NTO enable data NTO_ENd. Additionally, the 1-1 on die termination circuit 300_11 may enable self-termination operation based on a select chip enable command SCE.

The target memory device performs data input/output operations according to an operation request RQ (S140).

The target memory device may perform a data input/output operation based on a command CMD for an operation request RQ received in operation S110. When the target memory device receives a read command according to a read request in operation S110, the target memory device may output a data signal DQ to the channel. When the target memory device receives a program command according to a write request in operation S110, the target memory device may receive a data signal DQ from the channel.

Taking FIG. 3 as an example, when the 1-1 non-volatile memory device 100_11 is a target memory device, the storage controller 200 and the 1-1 non-volatile memory device 100_11 may transmit and receive a data signal DQ through a plurality of seventh pins P7 and a plurality of 1-7 pins P17.

The storage controller 200 checks whether data input/output operations according to an operation request RQ have been completed for the plurality of non-volatile memory devices (S150).

Taking FIG. 3 as an example, the storage controller 200 may check whether data input/output operations for the 1-1 and 1-2 non-volatile memory devices 100_11, 100_12 are completed.

If the storage controller 200 determines that a data input/output operation according to an operation request RQ for a plurality of non-volatile memory devices has not been completed, the storage controller 200 disables a self-termination operation for a previous target memory device and enables an NTO operation for the previous target memory device based on a select chip terminate command SCT corresponding to a select chip enable command SCE (S160).

If it is determined in operation S150 that the data input/output operation according to the operation request RQ for a plurality of non-volatile memory devices has not been completed, the storage device 10a may repeat operations S160 and S130 to S150.

The storage controller 200 may generate a select chip terminate command SCT for the target memory device in the previous operation S140 and provide the select chip terminate command SCT to the previous target memory device to disable the self-termination operation and enable the NTO operation.

The previous target memory device receives a select chip terminate command SCT, and the on die termination circuit 300 of the previous target memory device may transition the select chip enable data SCEd to a logic high level.

The on die termination circuit 300 of the previous target memory device may disable self-termination operation based on a select chip terminate command SCT. In addition, since the plurality of non-volatile memory devices receive the NTO enable command NTO_EN from the storage controller 200 in operation S120, the on die termination circuit 300 of the previous target memory device may enable the NTO operation based on the rising edge of the first NTO merge signal NTOms1, which is a logical AND operation value of the selection enable pulse signal SCEp for the select chip enable data SCEd and the inverted NTO enable pulse signal NTO_ENpb for the NTO enable data NTO_ENd.

Taking FIG. 3 as an example, if the 1-1 non-volatile memory device 100_11 is a previous target memory device, the storage controller 200 may generate a select chip terminate command SCT corresponding to a select chip enable command SCE for the 1-1 non-volatile memory device 100_11. The generated select chip terminate command SCT may be provided to the 1-1 non-volatile memory device 100_11 through the first and second pins P1 to P2 and the 1-1 to 1-2 pins P11 to P12. The 1-1 non-volatile memory device 100_11 receives a select chip terminate command SCT through a command address signal CA, and the 1-1 on die termination circuit 300_11 may disable a self-termination operation based on the select chip terminate command SCT. Additionally, the 1-1 on die termination circuit 300_11 may transition the select chip enable data SCEd to a logic low level. Since the 1-1 and 1-2 non-volatile memory devices 100_11, 100_12 receive an NTO enable command NTO_EN from the storage controller 200 in operation S120, the first on die termination circuit 300_11 may enable an NTO operation based on the rising edge of the first NTO merge signal NTOms1, which is a logical AND operation value of the inverted data of the select chip enable data SCEd and the NTO enable data NTO_ENd.

When the storage controller 200 determines that data input/output operations according to operation requests RQ for the plurality of non-volatile memory devices have been completed, the storage controller 200 disables NTO operations for the plurality of non-volatile memory devices connected to the channel based on an NTO disable command NTO_DIS (S170).

The storage controller 200 may generate an NTO disable command NTO_DIS for a plurality of non-volatile memory devices sharing a channel, and may provide the NTO disable command NTO_DIS to the plurality of non-volatile memory devices to disable NTO operations for the plurality of non-volatile memory devices.

A plurality of non-volatile memory devices receive an NTO disable command NTO_DIS, and an on die termination circuit 300 of each of the plurality of non-volatile memory devices may transition NTO enable data NTO_ENd to a logic low level. An on die termination circuit 300 of a plurality of non-volatile memory devices may disable an NTO operation based on an NTO clear signal NTOcs, which is a logical OR operation value of an NTO pulse signal NTOp for select chip enable data SCEd and an inverted NTO enable pulse signal NTO_ENpb for NTO enable data NTO_ENd.

Taking FIG. 3 as an example, the storage controller 200 may generate an NTO disable command NTO_DIS for all of the 1-1 and 1-2 non-volatile memory devices 100_11, 100_12 connected to the first channel CH1. The generated NTO disable command NTO_DIS may be provided to the 1-1 and 1-2 non-volatile memory devices 100_11, 100_12 through the first and second pins P1 to P2. The 1-1 and 1-2 non-volatile memory devices 100_11, 100_12 receive an NTO disable command NTO_DIS through a command address signal CA, and each of the first and second on die termination circuits 300_11, 300_12 may transition NTO enable data NTO_ENd to a logic low level. The first and second on die termination circuits 300_11, 300_12 may disable the NTO operation based on an NTO clear signal NTOcs, which is a logical OR operation value of a selection enable pulse signal SCEp for the select chip enable data SCEd and an inverted NTO enable pulse signal NTO_ENpb for the NTO enable data NTO_ENd.

The on die termination circuit 300 may control the NTO operation based on a select chip enable command SCE or a select chip terminate command SCT related to a data input/output operation through a non-target ODT circuit 310.

The storage device 10a may control the NTO operation based on the select chip enable command SCE or the select chip terminate command SCT without additional issuance of the NTO enable command NTO_EN and the NTO disable command NTO_DIS through the non-target ODT circuit 310, thereby improving the data input/output efficiency of the storage device 10a.

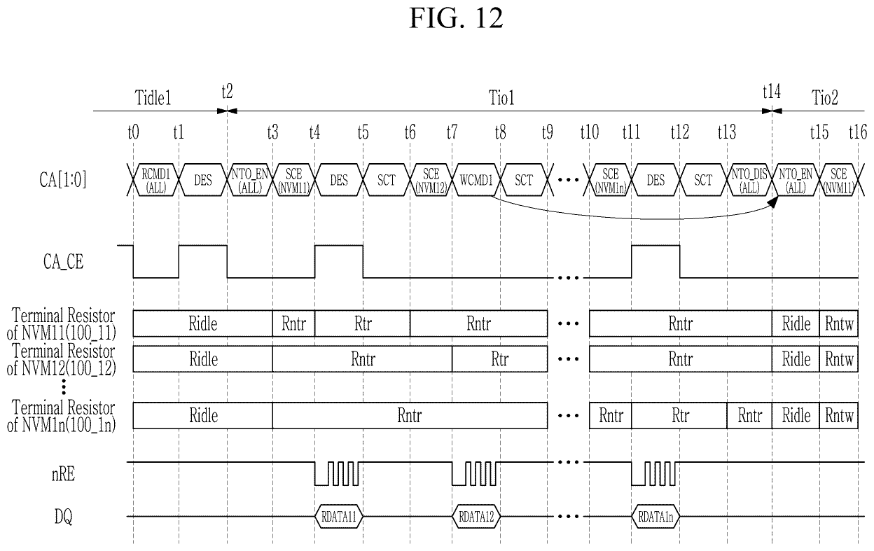

FIG. 12 is a timing diagram illustrating a method of operating a storage device according to some embodiments. Specifically, FIG. 12 illustrates an operation sequence of a storage device 10 a when the 1-1 to 1-n non-volatile memory devices 100_11 to 100_1n connected to the first channel CH1 of FIG. 2 perform a read operation and a program operation.

Referring to FIGS. 1 to 8 and 12, before time t0, the storage controller 200 may receive an operation request RQ for a first read command RCMD1 from the host device 20. In the first waiting period Tidle1, the 1-1 to 1-n non-volatile memory devices 100_11 to 100_1n may deactivate the ODT operation and not perform input/output operations of the data signal DQ. Since the ODT operation is disabled, the termination resistor for the data pins of the 1-1 to 1-n non-volatile memory devices 100_11 to 100_1n may be an idle resistance Ridle.

At time t0, the chip enable signal CA_CE may transition from a logic high level to a logic low level and may be maintained at a logic low level until time t1, and from time t0 to time t1, the storage controller 200 may provide a first read command RCMD1 for all of the 1-1 to 1-n non-volatile memory devices 100_11 to 100_1n to the 1-1 to 1-n non-volatile memory devices 100_11 to 100_1n through the first and second pins P1 to P2.

At time t1, the chip enable signal CA_CE transitions from a logic low level to a logic high level and is maintained at the logic high level until time t2, so that the 1-1 to 1-n non-volatile memory devices 100_11 to 100_1n may be deselected (DES) upon input of the command address signal CA from time t1 to time t2.

At time t2, the chip enable signal CA_CE transitions from a logic high level to a logic low level and is maintained at a logic low level until time t4, and from time t2 to time t3, the storage controller 200 may provide an NTO enable command NTO_EN for all of the 1-1 to 1-n non-volatile memory devices 100_11 to 100_1n to the 1-1 to 1-n non-volatile memory devices 100_11 to 100_1n through the first and second pins P1 to P2. The NTO enable command NTO_EN transmitted and received from time point t2 to time point t3 may be based on the first read command RCMD1.

At time t3, based on the NTO enable command NTO_EN, the NTO operation for the 1-1 to 1-n non-volatile memory devices 100_11 to 100_1n is enabled, so that the termination resistor for the data pin of the 1-1 to 1-n non-volatile memory devices 100_11 to 100_1n may be set to a read non-target termination resistance Rntr. From time t3 to time t4, the storage controller 200 may provide a select chip enable command SCE for the 1-1 non-volatile memory device 100_11 to the 1-1 to 1-n non-volatile memory devices 100_11 to 100_1n through the first and second pins P1 to P2. Although the NTO operation is enabled and the select chip enable command SCE is output without a time interval after the output of the NTO enable command NTO_EN in FIG. 12, it is not limited thereto, and depending on the embodiment, there may be a time interval between the output of the NTO enable command NTO_EN and the enablement of the NTO operation, and between the output of the NTO enable command NTO_EN and the output of the select chip enable command SCE.

At time t4, based on a select chip enable command SCE, an NTO operation for the 1-1 non-volatile memory device 100_11 is disabled and a self-termination operation for the 1-1 non-volatile memory device 100_11 is enabled, so that a termination resistor for a data pin of the 1-1 non-volatile memory device 100_11 may be set to a read target termination resistance Rtr. From time t4 to time t5, the 1-1 non-volatile memory device 100_11 as a target memory device may output a data signal DQ of the 1-1 read data RDATA11 through a data pin based on the first read command RCMD1, and the read enable signal nRE may be toggled. At time t4, the chip enable signal CA_CE transitions from a logic low level to a logic high level and is maintained at the logic high level until time t5, so that the 1-1 to 1-n non-volatile memory devices 100_11 to 100_1n may be deselected (DES) upon input of the command address signal CA from time t4 to time t5.

At time t5, the chip enable signal CA_CE transitions from a logic high level to a logic low level, and from time t5 to time t6, the storage controller 200 may provide a select chip terminate command SCT for the 1-1 non-volatile memory device 100_11 to the 1-1 to 1-n non-volatile memory devices 100_11 to 100_1n through the first and second pins P1 to P2. Although the output of the data signal DQ for the 1-1 read data RDATA11 and the output of the select chip terminate command SCT for the 1-1 non-volatile memory device 100_11 are depicted as being temporally separated in FIG. 12, this is not limited thereto, and according to an embodiment, the output of the data signal DQ for the 1-1 read data RDATA11 and the output of the select chip terminate command SCT may be performed simultaneously in some sections.

At time t6, based on a select chip terminate command SCT, a self-termination operation for the 1-1 non-volatile memory device 100_11 is disabled, an NTO operation for the 1-1 non-volatile memory device 100_11 is enabled, and a termination resistor for a data pin of the 1-1 non-volatile memory device 100_11 may be set to a read non-target termination resistance Rntr. From time t6 to time t7, the storage controller 200 may provide a select chip enable command SCE for the 1-2 non-volatile memory device 100_12 to the 1-1 to 1-n non-volatile memory devices 100_11 to 100_1n through the first and second pins P1 to P2. Although the NTO operation is enabled and the select chip enable command SCE is output without a time interval after the output of the select chip terminate command SCT in FIG. 12, it is not limited thereto, and depending on the embodiment, there may be a time interval between the output of the select chip terminate command SCT and the enablement of the NTO operation and between the output of the select chip terminate command SCT and the output of the select chip enable command SCE.

At time t7, based on a select chip enable command SCE, an NTO operation for the 1-2 non-volatile memory device 100_12 is disabled and a self-termination operation for the 1-2 non-volatile memory device 100_12 is enabled, so that a termination resistor for a data pin of the 1-2 non-volatile memory device 100_12 may be set to a read target termination resistance Rtr.

From time t7 to time t8, the 1-2 non-volatile memory device 100_12 as a target memory device may output a data signal DQ of the 1-2 read data RDATA12 through a data pin based on the first read command RCMD1, and the read enable signal nRE may be toggled. Additionally, the storage controller 200 may provide a first program command WCMD1 for all of the 1-1 to 1-n non-volatile memory devices 100_11 to 100_1n to the 1-1 to 1-n non-volatile memory devices 100_11 to 100_1n through the first to second pins P1 to P2.

From time t8 to time t9, the storage controller 200 may provide a select chip terminate command SCT for the 1-2 non-volatile memory device 100_12 to the 1-1 to 1-n non-volatile memory devices 100_11 to 100_1n through the first and second pins P1 to P2. In FIG. 12, the output for the 1-2 read data RDATA12 and the output of the select chip terminate command SCT for the 1-2 non-volatile memory device 100_12 are shown as being temporally separated, but are not limited thereto and may be performed simultaneously in some time intervals according to embodiments.

From time t10 to time t11, the chip enable signal CA_CE is maintained at a logic low level, and the storage controller 200 may provide a select chip enable command SCE for the 1-n non-volatile memory device 100_1n to the 1-1 to 1-n non-volatile memory devices 100_11 to 100_1n through the first and second pins P1 to P2.

At time t11, based on a select chip enable command SCE, an NTO operation for the 1-n non-volatile memory device 100_1n is disabled and a self-termination operation for the 1-n non-volatile memory device 100_1n is enabled, so that a termination resistor for a data pin of the 1-n non-volatile memory device 100_1n may be set to a read target termination resistance Rtr. From time t11 to time t12, the 1-n non-volatile memory device 100_1n may output a data signal DQ of the 1-n read data RDATA1n through a data pin based on the first read command RCMD1 as a target memory device, and the read enable signal nRE may be toggled. At time t11, the chip enable signal CA_CE transitions from a logic low level to a logic high level and is maintained at the logic high level until time t12, so that the 1-1 to 1-n non-volatile memory devices 100_11 to 100_1n may be deselected (DES) upon input of the command address signal CA from time t11 to time t12.

At time t12, the chip enable signal CA_CE transitions from a logic high level to a logic low level, and from time t12 to time t13, the storage controller 200 may provide a select chip terminate command SCT for the 1-n non-volatile memory device 100_1n to the 1-1 to 1-n non-volatile memory devices 100_11 to 100_1n through the first and second pins P1 to P2. In FIG. 12, the output of the data signal DQ for the 1-n read data RDATA1n and the output of the select chip terminate command SCT for the 1-n non-volatile memory device 100_1n are depicted as being temporally separated, but are not limited thereto and may be performed simultaneously in some time intervals according to embodiments.

At time t13, a self-termination operation for the 1-n non-volatile memory device 100_1n is disabled based on a select chip terminate command SCT, an NTO operation for the 1-n non-volatile memory device 100_1n is enabled, and a termination resistor for a data pin of the 1-n non-volatile memory device 100_1n may be set to a read non-target termination resistance Rntr. From time t13 to time t14, the storage controller 200 may provide an NTO disable command NTO_DIS for all of the 1-1 to 1-n non-volatile memory devices 100_11 to 100_1n to the 1-1 to 1-n non-volatile memory devices 100_11 to 100_1n through the first and second pins P1 to P2. The NTO disable command NTO_DIS transmitted and received from time point t13 to time point t14 may be based on the first read command RCMD1.

At time t14, based on the NTO disable command NTO_DIS, the NTO operation for the 1-1 to 1-n non-volatile memory devices 100_11 to 100_1n is disabled, so that the termination resistor for the data pins of the 1-1 to 1-n non-volatile memory devices 100_11 to 100_1n may be set to an idle resistance Ridle.

In a first data input/output period Tio1 for the 1-1 to 1-n non-volatile memory devices 100_11 to 100_1n based on a first read command RCMD1, an NTO operation for the 1-1 to 1-n non-volatile memory devices 100_11 to 100_1n may be controlled by an NTO enable command NTO_EN and an NTO disable command NTO_DIS as well as a select chip enable command SCE and a select chip terminate command SCT. By controlling the NTO operation by the NTO enable command NTO_EN, the NTO disable command NTO_DIS, the select chip enable command SCE, and the select chip terminate command SCT as described above, the 1-1 to 1-n non-volatile memory devices 100_11 to 100_1n may efficiently perform data input/output operations in the first data input/output period Tio1. For example, the storage controller 200 may output an NTO enable command NTO_EN for all of the 1-1 to 1-n non-volatile memory devices 100_11 to 100_1n from time t2 to time t3, and may continuously output a select chip enable command SCE for the 1-1 non-volatile memory device 100_11 from time t3 to time t4 to control the NTO operation of the 1-1 non-volatile memory device 100_11.

From time t14 to time t15, the storage controller 200 may provide an NTO enable command NTO_EN for all of the 1-1 to 1-n non-volatile memory devices 100_11 to 100_1n to the 1-1 to 1-n non-volatile memory devices 100_11 to 100_1n through the first and second pins P1 to P2. The NTO enable command NTO_EN transmitted and received from time point t14 to time point t15 may be based on the first program command WCMD1.

At time t15, an NTO operation for the 1-1 to 1-n non-volatile memory devices 100_11 to 100_1n is enabled based on an NTO enable command NTO_EN, so that a termination resistor for a data pin of the 1-1 to 1-n non-volatile memory devices 100_11 to 100_1n may be set to a write non-target termination resistance Rntw. From time t15 to time t16, the storage controller 200 may provide a select chip enable command SCE for the 1-1 non-volatile memory device 100_11 to the 1-1 to 1-n non-volatile memory devices 100_11 to 100_1n through the first and second pins P1 to P2. Although the NTO operation is enabled and the select chip enable command SCE is output without a time interval after the output of the NTO enable command NTO_EN in FIG. 12, it is not limited thereto, and depending on the embodiment, there may be a time interval between the output of the NTO enable command NTO_EN and the enablement of the NTO operation, and between the output of the NTO enable command NTO_EN and the output of the select chip enable command SCE.

After the time point t16, in the second data input/output period Tio2, the 1-1 to 1-n non-volatile memory devices 100_11 to 100_1n may perform an input operation of a data signal DQ based on the first program command WCMD1 by controlling the NTO operation by the NTO enable command NTO_EN, the NTO disable command NTO_DIS, the select chip enable command SCE, and the select chip terminate command SCT.

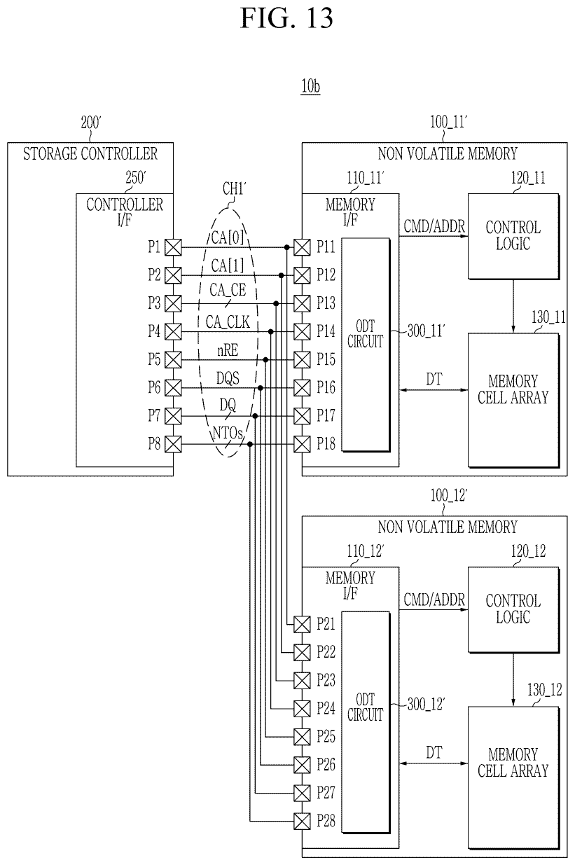

FIG. 13 is a block diagram illustrating a storage device according to some embodiments. Each of the storage device 10b, the storage controller 200′, the controller interface circuit 250′, the 1-1 and 1-2 non-volatile memory devices 100_11′, 100_12′, the 1-1 and 1-2 memory interface circuits 100_11′, 100_12′, and the 1-1 and 1-2 on die termination circuits 300_11′, 300_12′ of FIG. 13 may correspond to each of the storage device 10a, the storage controller 200, the controller interface circuit 250, the 1-1 and 1-2 non-volatile memory devices 100_11, 100_12, the 1-1 and 1-2 memory interface circuits 100_11, 100_12, and the 1-1 and 1-2 on die termination circuits 300_11, 300_12 of FIG. 3. For ease of the explanation below, the storage device 10b will be described below focusing on the differences from the storage device 10a of FIG. 3.

Referring to FIG. 13, the storage controller 200′ may further include an eighth pin P8, and the controller interface circuit 250′ may transmit an NTO signal NTOs through the eighth pin P8 separate from the first to seventh pins P1 to P7.

The 1-1 non-volatile memory device 100_11′ may further include a 1-8 pin P18, and the 1-1 memory interface circuit 110_11′ may receive an NTO signal NTOs through the 1-8 pin P18 that is separate from the 1-1 to 1-7 pins P11 to P17.

The 1-2 non-volatile memory device 100_12′ may further include a 2-8 pin P28, and the 1-2 memory interface circuit 110_12′ may receive an NTO signal NTOs through the 2-8 pin P28 that is separated from the 2-1 to 2-7 pins P21 to P27.

The 1-1 on die termination circuit 300_11′ of the 1-1 memory interface circuit 110_11′ may perform an ODT operation of setting termination resistors for a plurality of 1-7 pins P17, which are data pins, based on command CMD received from the 1-1 to 1-2 pins P11 to P12 and NTO signals NTOs received from the 1-8 pins P18, and connecting the termination resistors with the plurality of 1-7 pins P17.

The 1-2 on die termination circuit 300_12′ of the 1-2 memory interface circuit 110_12′ may perform an ODT operation of setting termination resistors for a plurality of 2-7 pins P27, which are data pins, based on command CMD received from the 2-1 to 2 -2 pins P21 to P22 and NTO signals NTOs received from the 2-8 pins P28, and connecting the termination resistors to the plurality of 2-7 pins P27.

The NTO signal NTOs may be provided to the 1-1 non-volatile memory device 100_11′ through the eighth pin P8 and the 1-8 pin P18, and may be provided to the 1-2nd non-volatile memory device 100_12′ through the eighth pin P8 and the 2-8 pin P28. The NTO signal NTOs may be a signal that globally controls the NTO operation of the 1-1 and 1-2 non-volatile memory devices 100_11′, 100_12′ connected to the first channel CH1′. For example, when the NTO signal NTOs maintains a logic high level and then transitions to a logic low level, the 1-1 and 1-2 non-volatile memory devices 100_11′, 100_12′ may enable the NTO operation.

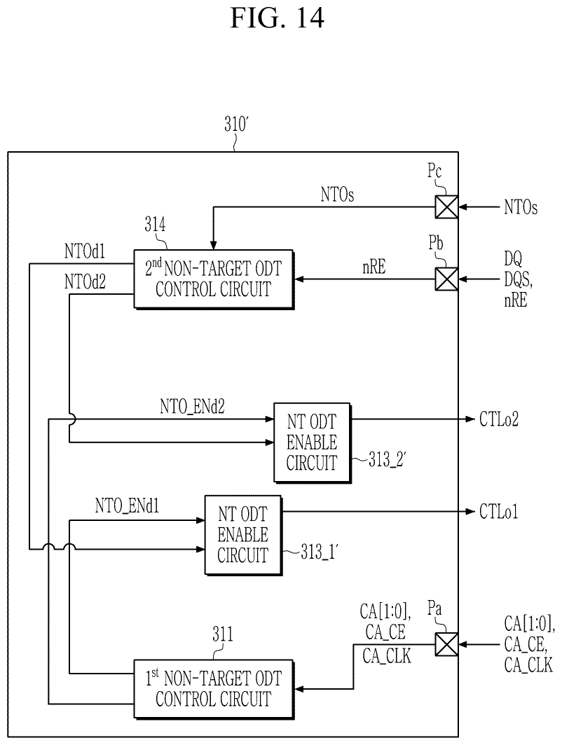

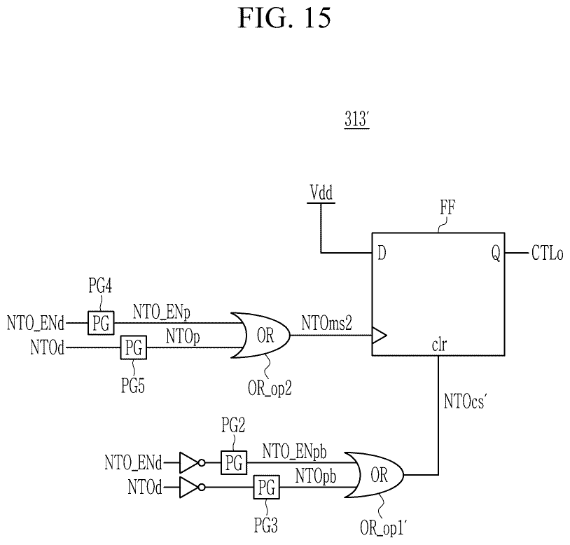

FIG. 14 is a block diagram illustrating a non-target ODT circuit according to some embodiments. FIG. 15 is a block diagram illustrating a non-target ODT enable circuit according to some embodiments. Each of the non-target ODT circuit 310′, the first non-target ODT control circuit 311, and the first and second NTO enable circuits 313_1′, 313_2′, and the NTO enable circuit 313′ of FIGS. 14 and 15 may correspond to each of the non-target ODT circuit 310, the first non-target ODT control circuit 311, and the first and second NTO enable circuits 313_1, 313_2, and the NTO enable circuit 313 of FIGS. 7 and 8. For ease of explanation below, the non-target ODT circuit 310′ of FIGS. 14 and 15 will be described with a focus on differences from the non-target ODT circuit 310 of FIGS. 7 and 8.

Referring to FIGS. 13 to 15, the non-target ODT circuit 310′ may include a first non-target ODT control circuit 311, first and second NTO enable circuits 313_1′, 313_2′, and a second non-target ODT control circuit 314. A non-target ODT circuit 310′ receives a command address signal CA, a chip enable signal CA_CE, a command address clock signal CA_CLK, a read enable signal nRE, and an NTO signal NTOs from a storage controller 200, and generates first and second ODT control signals CTLo1, CTLo2 based on the command address signal CA, the chip enable signal CA_CE, and the NTO signal NTOs to control an NTO operation of an on die termination circuit 300_11′, 300_12′.

The second non-target ODT control circuit 314 may receive a read enable signal nRE from the b-th pin Pb and an NTO signal NTOs from the c-th pin Pc, and generate NTO data NTOd1, NTOd2 based on the read enable signal nRE and the NTO signal NTOs. The b-th pin Pb may correspond to the 1-5 to 1-7 and 2-5 to 2-7 pins (P15 to P17, P25 to P27) of FIG. 13, and the c-th pin Pc may correspond to the 1-8 and 2-8 pins P18, P28 of FIG. 13.

For example, when the second non-target ODT control circuit 314 receives an NTO signal NTOs of a logic low level, it may transition the level of at least one NTO data NTOd1, NTOd2. In addition, the second non-target ODT control circuit 314 may transition the level of at least one NTO data NTOd1, NTOd2 in consideration of the data input/output situation in the first channel CH1′ in response to whether the read enable signal nRE is toggled.

Additionally, the second non-target ODT control circuit 314 may transition the NTO data NTOd1, NTOd2 to a logic low level in response to receiving an NTO signal NTOs of a logic high level.

The first NTO enable circuit 313_1′ may receive the first NTO enable data NTO_ENd1 and the first NTO data NTOd1, and output the first ODT control signal CTLo1 based on a logical operation on the first NTO enable data NTO_ENd1 and the first NTO data NTOd1. The second NTO enable circuit 313_2′ may receive second NTO enable data NTO_ENd2 and second NTO data NTOd2, and output a second ODT control signal CTLo2 based on a logical operation on the second NTO enable data NTO_ENd2 and second NTO data NTOd2.

In FIG. 15, the NTO enable circuit 313′ illustrates an exemplary circuit for a first NTO enable circuit 313_1′ and a second NTO enable circuit 313_2′. The NTO enable data NTO_ENd may correspond to the first and second NTO enable data NTO_ENd1, NTO_ENd2, the NTO data NTOd may correspond to the first and second NTO data NTOd1, NTOd2, and the ODT control signal CTLo may correspond to the first and second ODT control signals CTLo1, CTLo2. For ease of the explanation below, the description of the first NTO enable circuit 313_1′ and the second NTO enable circuit 313_2′ is replaced with the description of the NTO enable circuit 313′.

The NTO enable circuit 313′ may include a flip-flop FF, a first OR operator OR_op1′, a second OR operator OR_op2, and second to fifth pulse generators PG2 to PG5.

The flip-flop FF may receive a high-voltage power supply voltage Vdd as an input signal, receive a second NTO merge signal NTOms2, which is a result value of a second OR operator OR_op2, as a clock signal, and output an ODT control signal CTLo. The flip-flop FF may receive the NTO clear signal NTOcs′, which is the result value of the first OR operator OR_op1′, as a reset signal and reset the ODT control signal CTLo.

In some embodiments, the flip-flop FF may output and latch an ODT control signal CTLo of a logic high level in response to a rising edge of the second NTO merge signal NTOms2. In some embodiments, the flip-flop FF may reset the ODT control signal CTLo in response to the NTO clear signal NTOcs′ transitioning to a logic high level.

The second OR operator OR_op2 may perform an OR operation on the NTO enable pulse signal NTO_ENp for the NTO enable data NTO_ENd and the NTO pulse signal NTOp for the NTO data NTOd to generate a second NTO merge signal NTOms2. The NTO enable pulse signal NTO_ENp may be a pulse signal generated by the fourth pulse generator PG4 based on the rising edge of the NTO enable data NTO_ENd. The NTO pulse signal NTOp may be a pulse signal generated by the fifth pulse generator PG5 based on the rising edge of the NTO data NTOd.

The first OR operator OR_op1′ may perform an OR operation on the inverted NTO enable pulse signal NTO_ENpb for the NTO enable data NTO_ENd and the inverted NTO pulse signal NTOp for the NTO data NTOd to generate an NTO clear signal NTOcs′. The inverted NTO enable pulse signal NTO_ENpb may be a pulse signal generated by the second pulse generator PG2 based on the falling edge of the NTO enable data NTO_ENd. The inverted NTO pulse signal NTOp may be a pulse signal generated by the third pulse generator PG3 based on the falling edge of the NTO data NTOd.

The NTO enable circuit 313′ may control the NTO operation through the operations of the above-described flip-flop FF, the first OR operator OR_op1′, the second OR operator OR_op2, and the second to fifth pulse generators PG2 to PG5.

For example, when an NTO enable command NTO_EN is input and the NTO enable data NTO_ENd transitions to a logic high level or an NTO signal NTOs at a logic low level is input and the NTO data NTOd transitions to a logic high level, the second NTO merge signal NTOms2 transitions to a logic high level and an ODT control signal CTLo at a logic high level may be output in response to the rising edge of the second NTO merge signal NTOms2. In addition, when the NTO disable command NTO_DIS is input and the NTO enable data NTO_ENd transitions to a logic low level or the NTO signal NTOs at a logic high level is input and the NTO data NTOd transitions to a logic low level, the NTO clear signal NTOcs′ transitions to a logic high level so that the ODT control signal CTLo may be reset to a logic low level.

The on die termination circuit may globally control NTO operation for a plurality of non-volatile memory devices based on at least one of an NTO enable command NTO_EN/NTO disable command NTO_DIS and an NTO signal NTOs via a non-target ODT circuit 310′.

The storage device 10b may advantageously perform the NTO operation according to the operating status of the storage device 10b by controlling the NTO operation of a plurality of non-volatile memory devices based on at least one of a command CMD and an NTO signal NTOs through a non-target ODT circuit 310′.

The storage device 10b may control the NTO operations of a plurality of non-volatile memory devices based on NTO packets such as an NTO enable command/NTO disable command depending on the operating situation, or may select to control the NTO operations of a plurality of non-volatile memory devices based on NTO signals NTOs received from a separate pin.

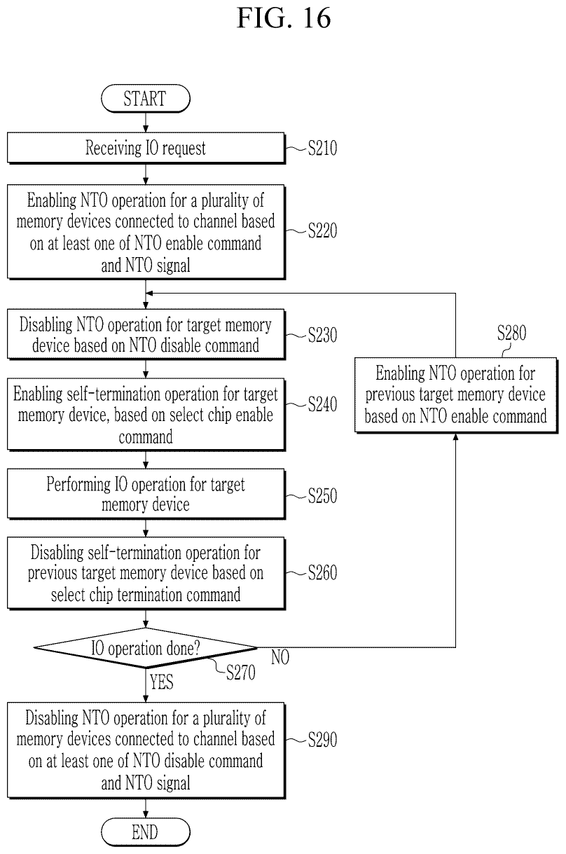

FIG. 16 is a flowchart illustrating a method of operating a storage device according to some embodiments.

Referring to FIGS. 13 to 16, the storage controller 200′ receives an operation request for data input/output from a host device (S210).

Operation S210 may correspond to operation S110 of FIG. 11, and for ease of explanation below, the description of operation S210 is replaced with the description of operation S110 of FIG. 11.

The storage controller 200′ enables NTO operation for a plurality of non-volatile memory devices connected to a channel based on at least one of an NTO enable command and an NTO signal NTOs (S220).

A storage controller 200′ may generate an NTO enable command or generate NTO signals NTOs of a logic low level for a plurality of non-volatile memory devices sharing a channel, and provide at least one of the NTO enable command and the NTO signals NTOs of a logic low level to the plurality of non-volatile memory devices to enable an NTO operation for the plurality of non-volatile memory devices.

A plurality of non-volatile memory devices receive at least one of an NTO enable command and an NTO signal NTOs of a logic low level, and an on die termination circuit of each of the plurality of non-volatile memory devices may transition at least one NTO enable data NTO_ENd to a logic high level or transition at least one NTO data NTOd to a logic high level. An on die termination circuit of a plurality of non-volatile memory devices may enable an NTO operation based on a second NTO merge signal NTOms2, which is a logical OR operation value of an NTO enable pulse signal NTO_ENp for NTO enable data NTO_ENd and an NTO pulse signal NTOp for NTO data NTOd, transitioning to a logic high level.

Taking FIG. 13 as an example, the storage controller 200′ may generate at least one of an NTO enable command and an NTO signal NTOs of a logic low level for all of the 1-1 and 1-2 non-volatile memory devices 100_11′, 100_12′ connected to the first channel CH1′. The generated NTO enable command may be provided to the 1-1 and 1-2 non-volatile memory devices 100_11′, 100_12′ through the first and second pins P1 to P2, and the generated NTO signal NTOs of logic low level may be provided to the 1-1 and 1-2 non-volatile memory devices 100_11′, 100_12′ through the eighth pin P8. The 1-1 and 1-2 non-volatile memory devices 100_11′, 100_12′ receive at least one of an NTO enable command and an NTO signal NTOs of a logic low level, and each of the 1-1 and 1-2 on die termination circuits 300_11′, 300_12′ may transition at least one NTO enable data NTO_ENd to a logic high level or transition at least one NTO data NTOd to a logic high level. The 1-1 and 1-2 on die termination circuits 300_11′, 300_12′ may enable an NTO operation based on the transition of a second NTO merge signal NTOms2, which is a logical OR operation value of an NTO enable pulse signal NTO_ENp for NTO enable data NTO_ENd and an NTO pulse signal NTOp for NTO data NTOd, to a logic high level.

The storage controller 200′ disables the NTO operation for the target memory device based on the NTO disable command (S230).

The storage controller 200′ may generate an NTO disable command for a target memory device among a plurality of non-volatile memory devices and provide the NTO disable command to the target memory device to disable the NTO operation.

Among the plurality of non-volatile memory devices, a target memory device receives an NTO disable command, and an on die termination circuit of the target memory device may transition NTO enable data NTO_ENd at a logic high level to a logic low level.

The on die termination circuit of the target memory device may disable the NTO operation based on an NTO clear signal NTOcs′, which is a logical OR operation value of an inverted NTO enable pulse signal NTO_ENpb for the NTO enable data NTO_ENd and an inverted NTO pulse signal NTOp for the NTO data NTOd.

Taking FIG. 13 as an example, a storage controller 200′ may generate an NTO disable command for the 1-1 non-volatile memory device 100_11′ among the 1-1 and 1-2 non-volatile memory devices 100_11′, 100_12′, and the 1-1 non-volatile memory device 100_11′ is a target memory device. The generated NTO disable command may be provided to the 1-1 non-volatile memory device 100_11′ through the first and second pins P1 to P2 and the 1-1 to 1-2 pins P11 to P12. The 1-1 non-volatile memory device 100_11′ receives an NTO disable command through a command address signal CA, and the 1-1 on die termination circuit 300_11′ may transition NTO enable data NTO_ENd at a logic high level to a logic low level. The 1-1 on die termination circuit 300_11′ may disable the NTO operation based on an NTO clear signal NTOcs′, which is a logical OR operation value of an inverted NTO enable pulse signal NTO_ENpb for the NTO enable data NTO_ENd and an inverted NTO pulse signal NTOp for the NTO data NTOd.

In an embodiment, when generating NTO signals NTOs of logic low level to enable NTO operations for the plurality of non-volatile memory devices, operation S230 may precede operation S220.

The storage controller 200′ enables self-termination operation for the target memory device based on the select chip enable command (S240).

The storage controller 200′ may generate a select chip enable command for the target memory device and provide the select chip enable command to the target memory device to enable a self-termination operation.

The on die termination circuitry of the target memory device may enable self-termination operation based on a select chip enable command.

Taking FIG. 13 as an example, the 1-1 on die termination circuit 300_11′ may enable self-termination operation based on a select chip enable command.

In some embodiments, when generating NTO signals NTOs of logic low level to enable NTO operations for the plurality of non-volatile memory devices, operations S240 and S220 may be performed together.

The target memory device performs data input/output operations according to the operation request (S250).

Operation S250 may correspond to operation S140 of FIG. 11, and for ease of explanation below, the description of operation S250 is replaced with the description of operation S140 of FIG. 11.

The storage controller 200′ disables the self-termination operation for the previous target memory device based on the select chip terminate command corresponding to the select chip enable command (S260).

The storage controller 200′ may generate a select chip terminate command for the target memory device in the previous operation S250 and provide the select chip terminate command to the previous target memory device to disable the self-termination operation.

On die termination circuitry of previous target memory devices may disable self-termination operation based on a select chip terminate command.

Taking FIG. 13 as an example, if the 1-1 non-volatile memory device 100_11′ is a previous target memory device, the storage controller 200′ may generate a select chip terminate command corresponding to a select chip enable command for the 1-1 non-volatile memory device 100_11′. The generated select chip terminate command may be provided to the 1-1 non-volatile memory device 100_11′ through the first and second pins P1 to P2 and the 1-1 to 1-2 pins P11 to P12. The 1-1 non-volatile memory device 100_11′ receives a select chip terminate command through a command address signal CA, and the 1-1 on die termination circuit 300_11′ may disable a self-termination operation based on the select chip terminate command.

The storage controller 200′ checks whether data input/output operations according to an operation request RQ have been completed for the plurality of non-volatile memory devices (S270).

Taking FIG. 13 as an example, the storage controller 200′ may check whether data input/output operations for the 1-1 and 1-2 non-volatile memory devices 100_11′, 100_12′ are completed.

If the storage controller 200′ determines that data input/output operations according to an operation request for the plurality of non-volatile memory devices have not been completed, the storage controller 200′ enables the NTO operation for the previous target memory device based on the NTO enable command (S280).

If it is determined in operation S270 that the data input/output operation according to the operation request has not been completed for a plurality of non-volatile memory devices, the storage device 10b may repeat operations S280 and S230 to S270.

The storage controller 200′ may generate an NTO enable command for the target memory device in the previous operation S250 and provide the NTO enable command to the previous target memory device to enable the NTO operation.

The previous target memory device receives an NTO enable command, and the on die termination circuit of the previous target memory device may transition at least one NTO enable data NTO_ENd to a logic high level.

The on die termination circuit of the previous target memory device may enable the NTO operation based on the second NTO merge signal NTOms2, which is the OR operation value of the NTO enable pulse signal NTO_ENp for the NTO enable data NTO_ENd and the NTO pulse signal NTOp for the NTO data NTOd, transitioning to a logic high level.

Taking FIG. 13 as an example, if the 1-1 non-volatile memory device 100_11′ is a previous target memory device, the storage controller 200′ may generate an NTO enable command for the 1-1 non-volatile memory device 100_11′. The generated NTO enable command may be provided to the 1-1 non-volatile memory device 100_11′ through the first and second pins P1 to P2 and the 1-1 to 1-2 pins P11 to P12. The 1-1 non-volatile memory device 100_11′ receives an NTO enable command through a command address signal CA, and the 1-1 on die termination circuit 300_11′ may transition at least one NTO enable data NTO_ENd to a logic high level based on the NTO enable command. The 1-1 on die termination circuit 300_11′ may enable an NTO operation based on the transition of a second NTO merge signal NTOms2, which is a logical OR operation value of an NTO enable pulse signal NTO_ENp for NTO enable data NTO_ENd and an NTO pulse signal NTOp for NTO data NTOd, to a logic high level.

When the storage controller 200′ determines that data input/output operations according to an operation request for a plurality of non-volatile memory devices have been completed, the storage controller 200′ disables the NTO operations for the plurality of non-volatile memory devices connected to the channel based on at least one of the NTO disable command and the NTO signals NTOs (S290).

A storage controller 200′ may generate an NTO disable command or generate NTO signals NTOs of a logic high level for a plurality of non-volatile memory devices sharing a channel, and may provide at least one of the NTO disable command and the NTO signals NTOs of a logic high level to the plurality of non-volatile memory devices to disable an NTO operation for the plurality of non-volatile memory devices.

A plurality of non-volatile memory devices receive at least one of an NTO disable command and an NTO signal NTOs of a logic high level, and an on die termination circuit of each of the plurality of non-volatile memory devices may transition the NTO enable data NTO_ENd of the logic high level to a logic low level or transition the NTO data NTOd of the logic high level to a logic low level. An on die termination circuit of a plurality of non-volatile memory devices may disable an NTO operation based on an NTO clear signal NTOcs′ which is a logical OR operation value of an inverted NTO enable pulse signal NTO_ENpb for NTO enable data NTO_ENd and an inverted NTO pulse signal NTOp for NTO data NTOd.

Taking FIG. 13 as an example, the storage controller 200′ may generate at least one of an NTO disable command and an NTO signal NTOs of a logic high level for all of the 1-1 and 1-2 non-volatile memory devices 100_11′, 100_12′ connected to the first channel CH1′. The generated NTO disable command may be provided to the 1-1 and 1-2 non-volatile memory devices 100_11′, 100_12′ through the first and second pins P1 to P2, and the generated NTO signal NTOs of logic high level may be provided to the 1-1 and 1-2 non-volatile memory devices 100_11′, 100_12′ through the eighth pin P8. The 1-1 and 1-2 non-volatile memory devices 100_11′, 100_12′ receive at least one of an NTO disable command and an NTO signal NTOs of a logic high level, and the 1-1 and 1-2 on die termination circuits 300_11′, 300_12′ each may transition NTO enable data NTO_ENd of a logic high level to a logic low level or transition NTO data NTOd of a logic high level to a logic low level. The 1-1 and 1-2 on die termination circuits 300_11′, 300_12′ may disable the NTO operation based on an NTO clear signal NTOcs′, which is a logical OR operation value of an inverted NTO enable pulse signal NTO_ENpb for the NTO enable data NTO_ENd and an inverted NTO pulse signal NTOp for the NTO data NTOd.

The storage device 10b controls the NTO operation of a plurality of non-volatile memory devices based on at least one of a command CMD and an NTO signal NTOs through a non-target ODT circuit 310′, and may advantageously perform the NTO operation depending on the operating status of the storage device 10b.

The storage device 10b may control the NTO operations of a plurality of non-volatile memory devices based on a command CMD such as an NTO enable command/NTO disable command depending on the operating situation, or may select to control the NTO operations of a plurality of non-volatile memory devices based on an NTO signal NTOs received from a separate pin.

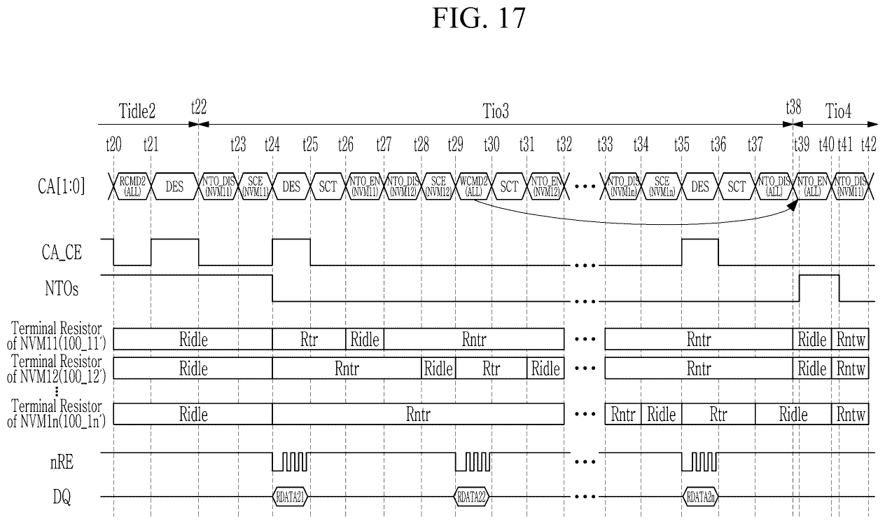

FIG. 17 is a timing diagram illustrating a method of operating a storage device according to some embodiments. Specifically, FIG. 17 illustrates an operation sequence of a storage device 10b when the 1-1 to 1-n non-volatile memory devices 100_11′ to 100_1n′ connected to the same channel perform a read operation and a program operation.

Referring to FIGS. 13 to 15 and FIG. 17, before time t20, the storage controller 200′ may receive an operation request for a second read command RCMD2 from the host device. In the second waiting period Tidle2, the 1-1 to 1-n non-volatile memory devices 100_11′ to 100_1n′ may deactivate the ODT operation and not perform the input/output operation of the data signal DQ. Since the ODT operation is disabled, the termination resistor for the data pins of the 1-1 to 1-n non-volatile memory devices 100_11′ to 100_1n′ may be an idle resistance Ridle.

At time t20, the chip enable signal CA_CE may transition from a logic high level to a logic low level and may be maintained at a logic low level until time t21, and from time t20 to time t21, the storage controller 200′ may provide a second read command RCMD2 to all of the first to second pins P1 to P2 to the 1-1 to the 1-n non-volatile memory devices 100_11′ to 100_1n′.

At time t21, the chip enable signal CA_CE transitions from a logic low level to a logic high level and is maintained at the logic high level until time t22, so that the 1-1 to 1-n non-volatile memory devices 100_11′ to 100_1n′ may be deselected(DES) upon input of the command address signal CA from time t21 to time t22.

At time t22, the chip enable signal CA_CE transitions from a logic high level to a logic low level and is maintained at the logic low level until time t24, and from time t22 to time t23, the storage controller 200′ may provide an NTO disable command NTO_DIS for the 1-1 non-volatile memory device 100_11′ to the 1-1 to 1-n non-volatile memory devices 100_11′ to 100_1n′ through the first and second pins P1 to P2. The transition to logic low level of the NTO disable command NTO_DIS and the NTO signal NTOs transmitted and received from time point t22 may be based on the second read command RCMD2.

At time t23, the NTO operation for the first non-volatile memory device 100_11′ is disabled based on the NTO disable command NTO_DIS, so that the termination resistor for the data pin of the first non-volatile memory device 100_11′ may be set to an idle resistance Ridle. From time t23 to time t24, the storage controller 200′ may provide a select chip enable command SCE for the 1-1 non-volatile memory device 100_11′ to the 1-1 to 1-n non-volatile memory devices 100_11′ to 100_1n′ through the first and second pins P1 to P2.

At time t24, a self-termination operation for the 1-1 non-volatile memory device 100_11′ is enabled based on a select chip enable command SCE, so that a termination resistor for a data pin of the 1-1 non-volatile memory device 100_11′ may be set to a read target termination resistance Rtr. Additionally, at time t24, the NTO signal NTOs may transition from a logic high level to a logic low level. Based on the transition of the NTO signal NTOs to a logic low level, the NTO operation for the 1-2nd to 1-n non-volatile memory devices (100_12′ to 100_1n′) other than the 1-1 non-volatile memory device 100_11′ is enabled, and the termination resistor for the data pin of the 1-2nd to 1-n non-volatile memory devices (100_12′ to 100_1n′) may be set to a read non-target termination resistance Rntr. At time t24, instead of outputting an NTO enable command for all of the 1-1 to 1-n non-volatile memory devices 100_11′ to 100_1n′, the storage controller 200′ may enable an NTO operation for all of the 1-2 to 1-n non-volatile memory devices (100_12′ to 100_1n′) excluding the 1-1 non-volatile memory device 100_11′, which is a target memory device, through a transition of an NTO signal NTOs at time t24.

In FIG. 17, the transition of the NTO signal NTOs to a logic low level and the completion of output of the select chip enable command SCE for the 1-1 non-volatile memory device 100_11′ are illustrated as being performed simultaneously, but are not limited thereto, and according to an embodiment, the transition of the NTO signal NTOs may precede the completion of output of the select chip enable command SCE for the 1-1 non-volatile memory device 100_11′.

From time t24 to time t25, the 1-1 non-volatile memory device 100_11′ may output a data signal DQ of the 2-1 read data RDATA21 through a data pin based on the second read command RCMD2 as a target memory device, and the read enable signal nRE may be toggled. At time t24, the chip enable signal CA_CE transitions from a logic low level to a logic high level and is maintained at the logic high level until time t25, so that the 1-1 to 1-n non-volatile memory devices 100_11′ to 100_1n′ may be deselected(DES) upon input of the command address signal CA from time t24 to time t25.

At time t25, the chip enable signal CA_CE transitions from a logic high level to a logic low level, and from time t25 to time t26, the storage controller 200′ may provide a select chip terminate command SCT for the 1-1 non-volatile memory device 100_11′ to the 1-1 to 1-n non-volatile memory devices 100_11′ to 100_1n′ through the first and second pins P1 to P2. Although the output of the data signal DQ for the 2_1 read data RDATA21 and the output of the select chip terminate command SCT for the 1-1 non-volatile memory device 100_11′ are depicted as being temporally separated in FIG. 17, this is not limited thereto, and according to an embodiment, the output of the data signal DQ for the 2_1 read data RDATA21 and the output of the select chip terminate command SCT may be performed simultaneously in some sections.

At time t26, the self-termination operation for the 1-1 non-volatile memory device 100_11′ may be disabled based on a select chip terminate command SCT, and the termination resistor for the data pin of the 1-1 non-volatile memory device 100_11′ may be set to an idle resistance Ridle. From time t26 to time t27, the storage controller 200′ may provide an NTO enable command NTO_EN for the 1-1 non-volatile memory device 100_11 to the 1-1 to 1-n non-volatile memory devices 100_11 to 100_1n through the first and second pins P1 to P2. Although it is illustrated in FIG. 17 that the self-termination operation is disabled and the NTO enable command NTO_EN is output without a time interval after the output of the select chip terminate command SCT, it is not limited thereto, and depending on the embodiment, there may be a time interval between the output of the select chip terminate command SCT and the disabling of the self-termination operation and between the output of the select chip terminate command SCT and the output of the NTO enable command NTO_EN.

At time t27, an NTO operation for the 1-1 non-volatile memory device 100_11′ is enabled based on an NTO enable command NTO_EN, and a termination resistor for a data pin of the 1-1 non-volatile memory device 100_11′ may be set to a read non-target termination resistance Rntr. From time t27 to time t28, the storage controller 200′ may provide an NTO disable command NTO_DIS for the 1-2 non-volatile memory device 100_12′ to the 1-1 to 1-n non-volatile memory devices 100_11′ to 100_1n′ through the first and second pins P1 to P2.

At time t28, the NTO operation for the 1-2 non-volatile memory device 100_12′ is disabled based on the NTO disable command NTO_DIS, so that the termination resistor for the data pin of the 1-2 non-volatile memory device 100_12′ may be set to an idle resistance Ridle. From time t28 to time t29, the storage controller 200′ may provide a select chip enable command SCE for the 1-2 non-volatile memory device 100_12′ to the 1-1 to 1-n non-volatile memory devices 100_11′ to 100_1n′ through the first and second pins P1 to P2.

At time t29, a self-termination operation for the 1-1 non-volatile memory device 100_11′ is enabled based on a select chip enable command SCE, so that a termination resistor for a data pin of the 1-1 non-volatile memory device 100_11′ may be set to a read target termination resistance Rtr. From time t29 to time t30, the 1-2 non-volatile memory device 100_12′ may output a data signal DQ of the 2_2 read data RDATA22 through a data pin based on the second read command RCMD2 as a target memory device, and the read enable signal nRE may be toggled. Additionally, the storage controller 200′ may provide a second program command WCMD2 for all of the 1-1 to 1-n non-volatile memory devices 100_11 to 100_1n to the 1-1 to 1-n non-volatile memory devices 100_11′ to 100_1n′ through the first and second pins P1 to P2.

From time t30 to time t31, the storage controller 200′ may provide a select chip terminate command SCT for the 1-2 non-volatile memory device 100_12′ to the 1-1 to 1-n non-volatile memory devices 100_11′ to 100_1n′ through the first and second pins P1 to P2. Although the output of the data signal DQ for the 2_2 read data RDATA22 and the output of the select chip terminate command SCT for the 1-2 non-volatile memory device 100_12′ are depicted as being temporally separated in FIG. 17, this is not limited thereto, and according to an embodiment, the output of the data signal DQ for the 2_2 read data RDATA22 and the output of the select chip terminate command SCT may be performed simultaneously in some sections.

At time t31, the self-termination operation for the 1-1 non-volatile memory device 100_11′ may be disabled based on a select chip terminate command SCT, and the termination resistor for the data pin of the 1-1 non-volatile memory device 100_11′ may be set to an idle resistance Ridle. From time t31 to time t32, the storage controller 200′ may provide an NTO enable command NTO_EN for the 1-2 non-volatile memory device 100_12′ to the 1-1 to 1-n non-volatile memory devices 100_11′ to 100_1n′ through the first and second pins P1 to P2. Although it is illustrated in FIG. 17 that the self-termination operation is disabled and the NTO enable command NTO_EN is output without a time interval after the output of the select chip terminate command SCT, it is not limited thereto, and depending on the embodiment, there may be a time interval between the output of the select chip terminate command SCT and the disabling of the self-termination operation and between the output of the select chip terminate command SCT and the output of the NTO enable command NTO_EN.

Although not illustrated, at time t32, an NTO operation for the 1-2 non-volatile memory device 100_12′ is enabled based on an NTO enable command NTO_EN, and a termination resistor for a data pin of the 1-2 non-volatile memory device 100_12′ may be set to a read non-target termination resistance Rntr.

From time t33 to time t34, the storage controller 200′ may provide an NTO disable command NTO_DIS for the 1-n non-volatile memory device 100_1n′ to the 1-1 to 1-n non-volatile memory devices 100_11′ to 100_1n′ through the first and second pins P1 to P2.

At time t34, the NTO operation for the 1-n non-volatile memory device 100_1n′ is disabled based on the NTO disable command NTO_DIS, so that the termination resistor for the data pin of the 1-n non-volatile memory device 100_1n′ may be set to an idle resistance Ridle. From time t34 to time t35, the storage controller 200′ may provide a select chip enable command SCE for the 1-n non-volatile memory device 100_1n′ to the 1-1 to 1-n non-volatile memory devices 100_11′ to 100_1n′ through the first and second pins P1 to P2.

At time t35, a self-termination operation for the 1-n non-volatile memory device 100_1n′ is enabled based on a select chip enable command SCE, so that a termination resistor for a data pin of the 1-n non-volatile memory device 100_1n′ may be set to a read target termination resistance Rtr. From time t35 to time t36, the 1-n non-volatile memory device 100_1n′ may output a data signal DQ of the 2-n read data RDATA2 n through a data pin based on the second read command RCMD2 as a target memory device, and the read enable signal nRE may be toggled. At time t35, the chip enable signal CA_CE transitions from a logic low level to a logic high level and is maintained at the logic high level until time t36, so that the 1-1 to 1-n non-volatile memory devices 100_11 to 100_1n may be deselected (DES) upon input of the command address signal CA from time t35 to time t36.

At time t36, the chip enable signal CA_CE transitions from a logic high level to a logic low level, and from time t36 to time t37, the storage controller 200′ may provide a select chip terminate command SCT for the 1-n non-volatile memory device 100_1n′ to the 1-1 to 1-n non-volatile memory devices 100_11′ to 100_1n′ through the first and second pins P1 to P2. Although the output of the data signal DQ for the 2-n read data RDATA2n and the output of the select chip terminate command SCT for the 1st_n non-volatile memory device 100_1n′ are depicted as being temporally separated in FIG. 17, this is not limited thereto, and depending on the embodiment, the output of the data signal DQ for the 2-n read data RDATA2n and the output of the select chip terminate command SCT may be performed simultaneously in some sections.

At time t37, the self-termination operation for the 1-n non-volatile memory device 100_1n′ is disabled based on a select chip terminate command SCT, and the termination resistor for the data pin of the 1-n non-volatile memory device 100_1n′ may be set to an idle resistance Ridle. From time t37 to time t38, the storage controller 200′ may provide an NTO disable command NTO_DIS for all of the 1-1 to 1-n non-volatile memory devices 100_11′ to 100_1n′ to the 1-1 to 1-n non-volatile memory devices 100_11′ to 100_1n′ through the first and second pins P1 to P2. The NTO disable command NTO_DIS transmitted and received from time point t37 to time point t38 may be based on the first read command RCMD1.

At time t38, based on the NTO disable command NTO_DIS, the NTO operation for the 1-1 to 1-n non-volatile memory devices 100_11′ to 100_1n′ is disabled, so that the termination resistor for the data pins of the 1-1 to 1-n non-volatile memory devices 100_11′ to 100_1n′ may be set to an idle resistance Ridle.

The storage device 10 b may disable the NTO operation for the 1-1 to 1-n non-volatile memory devices 100_11′ to 100_1n′ based on an NTO disable command NTO_DIS for all of the 1-1 to 1-n non-volatile memory devices 100_11′ to 100_1n′, instead of the NTO signal NTOs that transitions to a logic high level at a time point t39 after a time point t38. In a third data input/output period Tio3 for the first to first n non-volatile memory devices 100_11′ to 100_1n′ based on the second read command RCMD2, an NTO operation for the first to first n non-volatile memory devices 100_11′ to 100_1n′ may be controlled by an NTO enable command NTO_EN and an NTO disable command NTO_DIS as well as an NTO signal NTOs. By controlling the NTO operation by the NTO enable command NTO_EN, NTO disable command NTO_DIS, and NTO signal NTOs as described above, the NTO operation may be advantageously performed depending on the operating status of the storage device 10b, thereby efficiently performing the data input/output operation in the third data input/output period Tio3.

From time t38 to time t40, the storage controller 200′ may provide an NTO enable command NTO_EN for all of the 1-1 to 1-n non-volatile memory devices 100_11′ to 100_1n′ to the 1-1 to 1-n non-volatile memory devices 100_11′ to 100_1n′ through the first and second pins P1 to P2. The NTO enable command NTO_EN transmitted and received from time point t38 to time point t40 may be based on the second program command WCMD2.

At time t40, based on the NTO enable command NTO_EN, the NTO operation for the 1-1 to 1-n non-volatile memory devices 100_11′ to 100_1n′ is enabled, so that the termination resistor for the data pin of the 1-1 to 1-n non-volatile memory devices 100_11′ to 100_1n′ may be set to a write non-target termination resistance Rntw.

The storage device 10b may enable an NTO operation for the 1-1 to 1-n non-volatile memory devices 100_11′ to 100_1n′ based on an NTO enable command NTO_EN for all of the 1-1 to 1-n non-volatile memory devices 100_11′ to 100_1n′, instead of an NTO signal NTOs that transitions to a logic low level at a time point t41 after a time point t40.

From time t40 to time t42, the storage controller 200′ may provide an NTO disable command NTO_DIS for the 1-1 non-volatile memory device 100_11′ to the 1-1 to 1-n non-volatile memory devices 100_11′ to 100_1n′ through the first and second pins P1 to P2. Although the NTO operation is enabled and the NTO disable command NTO_DIS is output without a time interval after the output of the NTO enable command NTO_EN in FIG. 17, it is not limited thereto, and depending on the embodiment, there may be a time interval between the output of the NTO enable command NTO_EN and the enabling of the NTO operation, and between the output of the NTO enable command NTO_EN and the output of the NTO disable command NTO_DIS.

After the t42 time point, in the fourth data input/output period Tio4, the 1-1 to 1-n non-volatile memory devices 100_11′ to 100_1n′ may perform an input operation of a data signal DQ based on the second program command WCMD2 by controlling the NTO operation by the NTO enable command NTO_EN, the NTO disable command NTO_DIS, and the NTO signal NTOs.

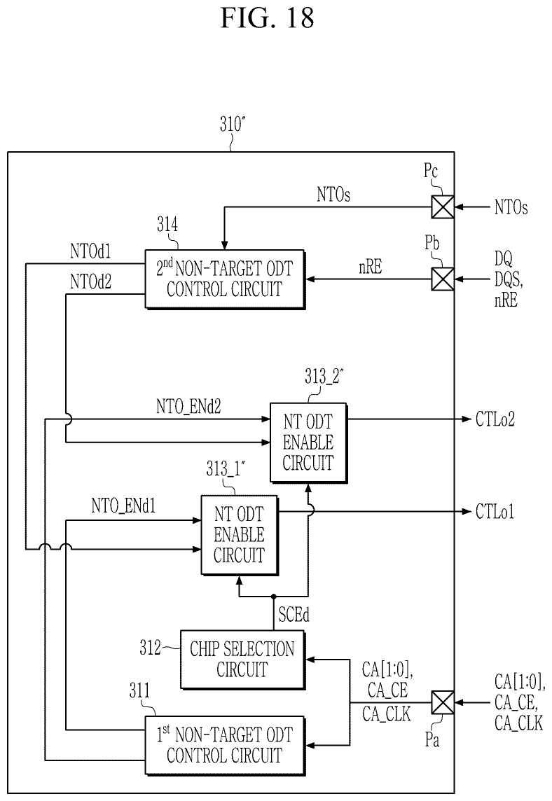

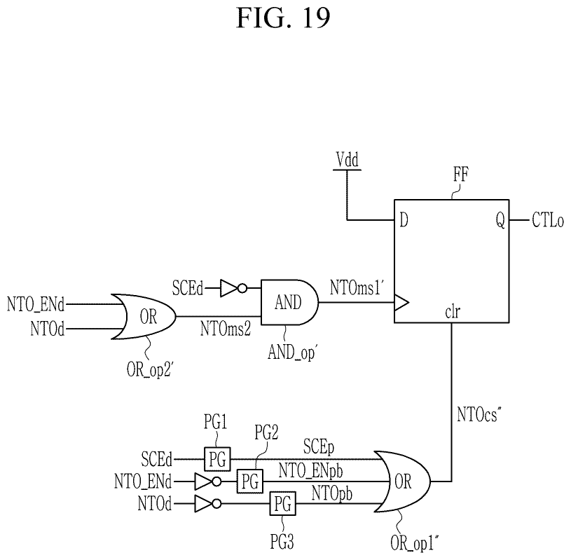

FIG. 18 is a block diagram illustrating a non-target ODT circuit according to some embodiments. FIG. 19 is a block diagram illustrating a non-target ODT enable circuit according to some embodiments.

Each of the non-target ODT circuit 310″, the first non-target ODT control circuit 311, and the first and second NTO enable circuits 313_1″, 313_2″, the second non-target ODT control circuit 314, and the NTO enable circuit 313′ of FIGS. 18 and 19 may correspond to each of the non-target ODT circuit 310′, the first non-target ODT control circuit 311, and the first and second NTO enable circuits 313_1′, 313_2′, the second non-target ODT control circuit 314, and the NTO enable circuit 313′ of FIGS. 14 and 15. For ease of explanation below, the non-target ODT circuit 310″ of FIGS. 18 and 19 will be described with a focus on differences from the non-target ODT circuit 310′ of FIGS. 14 and 15.

Referring to FIGS. 18 and 19, the non-target ODT circuit 310″ may include a first non-target ODT control circuit 311, a chip selection circuit 312, first and second NTO enable circuits 313_1″, 313_2″, and a second non-target ODT control circuit 314. A non-target ODT circuit 310″ receives a command address signal CA, a chip enable signal CA_CE, a command address clock signal CA_CLK, a read enable signal nRE, and an NTO signal NTOs from a storage controller, and generates first and second ODT control signals CTLo1, CTLo2 based on the command address signal CA, the chip enable signal CA_CE, and the NTO signal NTOs to control an NTO operation of an on die termination circuit.

The chip selection circuit 312 may receive a command address signal CA, a chip enable signal CA_CE, and a command address clock signal CA_CLK from the a-th pin Pa, and decode a command CMD and an address ADDR in the form of a CA packet for the command address signal CA, thereby generating a select chip enable data SCEd. The chip selection circuit 312 may be applied with the description of the chip selection circuit 312 of FIG. 7.

The first NTO enable circuit 313_1″ may receive the first NTO enable data NTO_ENd1, the select chip enable data SCEd, and the first NTO data NTOd1, and output the first ODT control signal CTLo1 based on a logical operation on the first NTO enable data NTO_ENd1, the select chip enable data SCEd, and the first NTO data NTOd1. The second NTO enable circuit 313_2″ receives second NTO enable data NTO_ENd2, select chip enable data SCEd, and second NTO data NTOd2, and may output a second ODT control signal CTLo2 based on a logical operation on the second NTO enable data NTO_ENd2 and the second NTO data NTOd2.

In FIG. 19, the NTO enable circuit 313″ illustrates an exemplary circuit for a first NTO enable circuit 313_1″ and a second NTO enable circuit 313_2″. The NTO enable data NTO_ENd may correspond to the first and second NTO enable data NTO_ENd1, NTO_ENd2, the NTO data NTOd may correspond to the first and second NTO data NTOd1, NTOd2, and the ODT control signal CTLo may correspond to the first and second ODT control signals CTLo1, CTLo2. For ease of the explanation below, the description of the first NTO enable circuit 313_1″ and the second NTO enable circuit 313_2″ is replaced with the description of the NTO enable circuit 313″.

The NTO enable circuit 313″ may include a flip-flop FF, a AND operator AND_op′, a first OR operator OR_op1″, a second OR operator OR_op2′, and first to third pulse generators PG1 to PG3.

The flip-flop FF may receive a high-voltage power supply voltage Vdd as an input signal, receive a first NTO merge signal NTOms1′, which is a result value of a AND operator AND_op′, as a clock signal, and output an ODT control signal CTLo. The flip-flop FF may receive the NTO clear signal NTOcs″, which is the result value of the first OR operator OR_op1″, as a reset signal and reset the ODT control signal CTLo.

According to some embodiments, the flip-flop FF may output and latch an ODT control signal CTLo of a logic high level in response to a rising edge of the first NTO merge signal NTOms1′. In some embodiments, the flip-flop FF may reset the ODT control signal CTLo in response to the NTO clear signal NTOcs″ transitioning to a logic high level.

The AND operator AND_op′ may perform a AND operation on the second NTO merge signal NTOms2′, which is the result value of the second OR operator OR_op2′, and the inverted data of the select chip enable data SCEd, thereby generating the first NTO merge signal NTOms1′. The second OR operator OR_op2′ may perform an OR operation on the NTO enable data NTO_ENd and the NTO data NTOd to generate a second NTO merge signal NTOms2′.

The first OR operator OR_op1″ may perform an OR operation on a select chip enable pulse signal SCEp for the select chip enable data SCEd, an inverted NTO enable pulse signal NTO_ENpb for the NTO enable data NTO_ENd, and an inverted NTO pulse signal NTOp for the NTO data NTOd, thereby generating an NTO clear signal NTOcs″.

The NTO enable circuit 313 may control the NTO operation through the operations of the above-described flip-flop FF, the AND operator AND_op′, the second OR operator OR_op2′, the first OR operator OR_op1″, and the first to third pulse generators PG1 to PG3.

For example, when an NTO enable command is input or an NTO signal NTOs at a logic low level is input and a select chip enable command is input and the select chip enable data SCEd transitions to a logic high level, the NTO clear signal NTOcs″ transitions to a logic high level so that the ODT control signal CTLo may be reset to a logic low level. In addition, when an NTO enable command is input or an NTO signal NTOs at a logic low level is input so that the second NTO merge signal NTOms2′ is maintained at a logic high level, and a select chip terminate command is input so that the select chip enable data SCEd transitions to a logic low level, the first NTO merge signal NTOms1′ transitions to a logic high level, and an ODT control signal CTLo at a logic high level may be output in response to a rising edge of the first NTO merge signal NTOms1′.

The on die termination circuit may control the NTO operation based on a select chip enable command or a select chip terminate command related to a data input/output operation through a non-target ODT circuit 310″.

For example, when a select chip enable command is not input and thus the select chip enable data SCEd maintains a logic low level, and an NTO enable command is input and thus the NTO enable data NTO_ENd transitions to a logic high level, or an NTO signal NTOs at a logic low level is input and thus the NTO data NTOd transitions to a logic high level, the first NTO merge signal NTOms1′ transitions to a logic high level, and an ODT control signal CTLo at a logic high level may be output in response to a rising edge of the first NTO merge signal NTOms1′. In addition, when an NTO disable command is input and the NTO enable data NTO_ENd transitions to a logic low level or an NTO signal NTOs at a logic high level is input and the NTO data NTOd transitions to a logic low level, the NTO clear signal NTOcs″ transitions to a logic high level so that the ODT control signal CTLo may be reset to a logic low level.

The on die termination circuit may globally control NTO operation for a plurality of non-volatile memory devices based on at least one of an NTO enable command/NTO disable command and an NTO signal NTOs via a non-target ODT circuit 310″.

The storage device may advantageously perform the NTO operation of a plurality of non-volatile memory devices based on at least one of a command CMD and an NTO signal NTOs through a non-target ODT circuit 310″, depending on the operating status of the storage device.

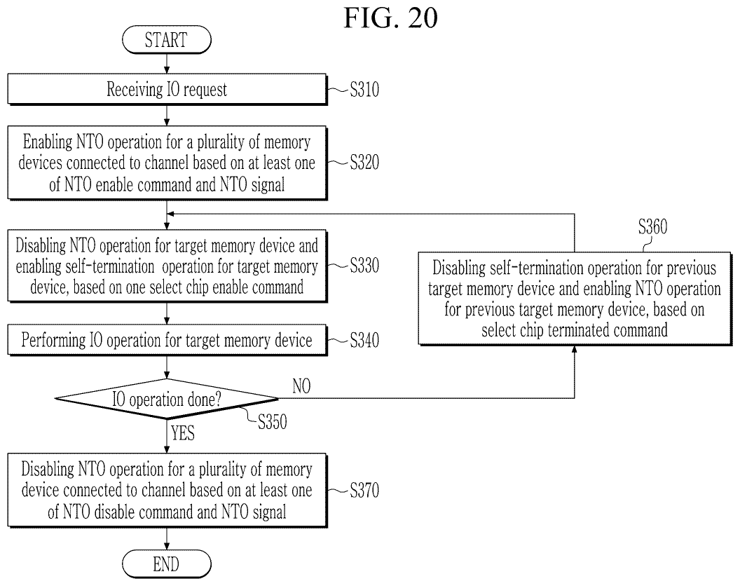

FIG. 20 is a flowchart illustrating a method of operating a storage device according to some embodiments. Specifically, FIG. 20 describes the operation of the storage device 10b of FIG. 13 including the 1-1 and 1-2 on die termination circuits 300_11′, 300_12′ to which the non-target ODT circuit 310″ of FIGS. 18 and 19 is applied. For ease of explanation below, the operation of the storage device 10b of FIG. 20 will be described with a focus on differences from the operation method of FIG. 16.

Referring to FIG. 13 and FIG. 18 to FIG. 20, the storage controller 200′ receives an operation request for data input/output from a host device (S310).

Operation S310 may correspond to operation S210 of FIG. 16, and for ease of explanation below, the description of operation S210 is replaced with the description of operation S310 of FIG. 16.

The storage controller 200′ enables NTO operation for a plurality of non-volatile memory devices connected to the channel based on at least one of the NTO enable command and the NTO signal (S320).

Operation S320 may correspond to operation S220 of FIG. 16, and for ease of explanation below, the description of operation S320 is replaced with the description of operation S220 of FIG. 16.

The storage controller 200′ disables the NTO operation for the target memory device and enables the self-termination operation for the target memory device based on the select chip enable command (S330).

Operation S330 may correspond to operation S130 of FIG. 11, and for ease of explanation below, the description of operation S330 is replaced with the description of operation S130 of FIG. 11.

The target memory device performs data input/output operations according to the operation request (S340).

The target memory device may perform a data input/output operation based on a command CMD for an operation request received in operation S310. When the target memory device receives a read command according to a read request in operation S310, the target memory device may output a data signal DQ to the channel. When the target memory device receives a program command according to a write request in operation S310, the target memory device may receive a data signal DQ from the channel.

Taking FIG. 13 as an example, when the 1-1 non-volatile memory device 100_11′ is a target memory device, the storage controller 200′ and the 1-1 non-volatile memory device 100_11′ may transmit and receive a data signal DQ through a plurality of seventh pins P7 and a plurality of 1-7 pins P17.

The storage controller 200 checks whether data input/output operations according to an operation request have been completed for the plurality of non-volatile memory devices (S350).

Taking FIG. 13 as an example, the storage controller 200′ may check whether data input/output operations for the 1-1 and 1-2 non-volatile memory devices 100_11′, 100_12′ are completed.

If the storage controller 200′ determines that data input/output operations according to an operation request for a plurality of non-volatile memory devices have not been completed, the storage controller 200′ disables a self-termination operation for a previous target memory device and enables an NTO operation for the previous target memory device based on a select chip terminate command corresponding to a select chip enable command (S360).

Operation S360 may correspond to operation S160 of FIG. 11, and for ease of explanation below, the description of operation S360 is replaced with the description of operation S160 of FIG. 11. If it is determined that data input/output operations according to an operation request have not been completed for the plurality of non-volatile memory devices in operation S360, the storage device 10b may repeat operations 360 and S330 to S350.

When the storage controller 200′ determines that data input/output operations according to an operation request for a plurality of non-volatile memory devices have been completed, the storage controller 200′ disables the NTO operations for the plurality of non-volatile memory devices connected to the channel based on at least one of the NTO disable command and the NTO signals NTOs (S370).

Operation S370 may correspond to operation S290 of FIG. 16, and for ease of explanation below, the description of operation S370 is replaced with the description of operation S290 of FIG. 16.

The on die termination circuit may control the NTO operation based on a select chip enable command or select chip terminate command related to data input/output operation through a non-target ODT circuit 310″ and an NTO signal NTOs received from a separate pin. The on die termination circuit may improve the efficiency of input/output operations of a storage device by controlling NTO operations through other types of commands and signals as well as NTO packets such as NTO enable command/NTO disable command.

The storage device 10b may control the NTO operation based on the select chip enable command SCE or the select chip terminate command SCT without additional issuance of the NTO enable command NTO_EN and the NTO disable command NTO_DIS through the non-target ODT circuit 310″, thereby improving the data input/output efficiency of the storage device 10a.

The storage device 10b controls the NTO operation of a plurality of non-volatile memory devices based on at least one of a command CMD and an NTO signal NTOs through a non-target ODT circuit 310″, and may advantageously perform the NTO operation depending on the operating status of the storage device 10b.

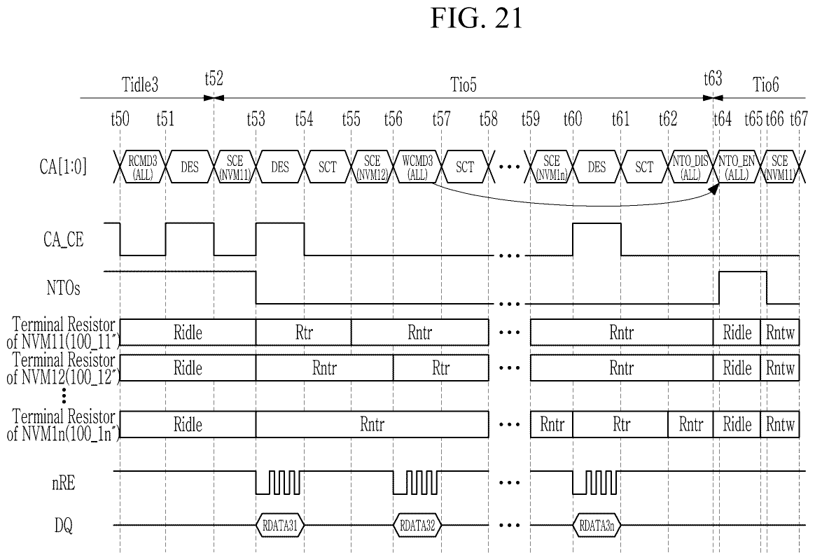

FIG. 21 is a timing diagram illustrating a method of operating a storage device according to some embodiments. Specifically, FIG. 21 illustrates an operation sequence of a storage device when the 1-1 to 1-n non-volatile memory devices 100_11″ to 100_1n″ connected to the same channel and to which the non-target ODT circuit 310″ of FIGS. 18 and 19 is applied perform a read operation and a program operation.

Referring to FIGS. 18, 19, and 21, prior to time t50, the storage controller may receive an operation request for a third read command RCMD3 from the host device. In the third waiting period Tidle3, the 1-1 to 1-n non-volatile memory devices 100_11″ to 100_1n″ may deactivate the ODT operation and not perform the input/output operation of the data signal DQ. Since the ODT operation is disabled, the termination resistor for the data pins of the 1-1 to 1-n non-volatile memory devices (100_11″ to 100_1n″) may be an idle resistance Ridle.

At time t50, the chip enable signal CA_CE may transition from a logic high level to a logic low level and may be maintained at the logic low level until time t51, and from time t50 to time t51, the storage controller may provide a third read command RCMD3 to all of the first-1 to 1-n non-volatile memory devices 100_11″ to 100_1n″ through the a-th pin Pa.

At time t51, the chip enable signal CA_CE transitions from a logic low level to a logic high level and is maintained at the logic high level until time t52, so that the 1-1 to 1-n non-volatile memory devices 100_11″ to 100_1n″ may be deselected (DES) upon input of the command address signal CA from time t51 to time t52.

At time t52, the chip enable signal CA_CE transitions from a logic high level to a logic low level and is maintained at the logic low level until time t53, and from time t52 to time t53, the storage controller 200′ may provide a select chip enable command SCE for the 1-1 non-volatile memory device 100_11″ to the 1-1 to 1-n non-volatile memory devices 100_11″ to 100_1n″ through the a-th pin Pa. The transition to logic low level of the NTO signal NTOs transmitted and received from time point t52 and the select chip enable command SCE transmitted and received from time point t52 to time point t53 may be based on the third read command RCMD3.

At time t53, based on a select chip enable command SCE, an NTO operation for the 1-1 non-volatile memory device 100_11″ is disabled and a self-termination operation for the 1-1 non-volatile memory device 100_11″ is enabled, so that a termination resistor for a data pin of the 1-1 non-volatile memory device 100_11″ may be set to a read target termination resistance Rtr. At time t53, the NTO signal NTOs may transition from a logic high level to a logic low level. Based on the transition of the NTO signal NTOs to a logic low level, the NTO operation for the 1-2nd to 1-1 non-volatile memory devices 100_12″ to 100_1n″ other than the 1-1 non-volatile memory device 100_11″ is enabled, and the termination resistor for the data pin of the 1-2nd to 1-1 non-volatile memory devices 100_12″ to 100_1n″ may be set to a read non-target termination resistance Rntr. At time t53, instead of outputting an NTO enable command for all of the 1-1 to 1-n non-volatile memory devices 100_11″ to 100_1n″, the storage controller may enable an NTO operation for all of the 1-2 to 1-n non-volatile memory devices 100_12″ to 100_1n″ through a transition of an NTO signal NTOs at time t53.

In FIG. 21, the transition of the NTO signal NTOs to a logic low level and the completion of outputting the select chip enable command SCE for the 1-1 non-volatile memory device 100_11″ are illustrated as being performed simultaneously, but are not limited thereto, and according to an embodiment, the transition of the NTO signal NTOs may precede the completion of outputting the select chip enable command SCE for the 1-1 non-volatile memory device 100_11″.

From time t53 to time t54, the 1-1 non-volatile memory device 100_11″ as a target memory device may output a data signal DQ of the 3-1 read data RDATA31 through a data pin based on the third read command RCMD3, and the read enable signal nRE may be toggled. At time t53, the chip enable signal CA_CE transitions from a logic low level to a logic high level and is maintained at the logic high level until time t54, so that the 1-1 to 1-1 non-volatile memory devices 100_11″ to 100_1n″ may be deselected (DES) upon input of the command address signal CA from time t53 to time t54.

At time t54, the chip enable signal CA_CE transitions from a logic high level to a logic low level, and from time t54 to time t55, the storage controller may provide a select chip terminate command SCT for the 1-1 non-volatile memory device 100_11″ to the 1-1 to 1-n non-volatile memory devices 100_11″ to 100_1n″ through the a-th pin Pa. Although the output of the data signal DQ for the 3-1 read data RDATA31 and the output of the select chip terminate command SCT for the 1-1 non-volatile memory device 100_11″ are depicted as being temporally separated in FIG. 21, the present disclosure is not limited thereto, and according to an embodiment, the output of the data signal DQ for the 3-1 read data RDATA31 and the output of the select chip terminate command SCT may be performed simultaneously in some sections.

At time t55, a self-termination operation for the 1-1 non-volatile memory device 100_11″ is disabled based on a select chip terminate command SCT, an NTO operation for the 1-1 non-volatile memory device 100_11″ is enabled, and a termination resistor for a data pin of the 1-1 non-volatile memory device 100_11″ may be set to a read non-target termination resistance Rntr. From time t55 to time t56, the storage controller may provide a select chip enable command SCE for the 1-2 non-volatile memory device 100_12″ to the 1-1 to 1-n non-volatile memory devices 100_11″ to 100_1n″ through the a-th pin Pa. Although the NTO operation is enabled and the select chip enable command SCE is output without a time interval after the output of the select chip terminate command SCT in FIG. 21, it is not limited thereto, and depending on the embodiment, there may be a time interval between the output of the select chip terminate command SCT and the enablement of the NTO operation and between the output of the select chip terminate command SCT and the output of the select chip enable command SCE.

At time t56, based on a select chip enable command SCE, an NTO operation for the 1-2 non-volatile memory device 100_12″ is disabled and a self-termination operation for the 1-2 non-volatile memory device 100_12″ is enabled, so that a termination resistor for a data pin of the 1-2 non-volatile memory device 100_12″ may be set to a read target termination resistance Rtr.

From time t56 to time t57, the 1-2 non-volatile memory device 100_12″ as a target memory device may output a data signal DQ of the 3-2 read data RDATA32 through a data pin based on the third read command RCMD3, and the read enable signal nRE may be toggled. Additionally, the storage controller may provide a third program command WCMD3 to all of the 1-1 to 1-n non-volatile memory devices 100_11″ to 100_1n″ through the a-th pin Pa.

From time t57 to time t58, the storage controller may provide a select chip terminate command SCT for the 1-2 non-volatile memory device 100_12″ to the 1-1 to 1-n non-volatile memory devices 100_11″ to 100_1n″ through the a-th pin Pa. In FIG. 21, the output for the 3-2 read data RDATA32 and the output of the select chip terminate command SCT for the 1-2 non-volatile memory device 100_12″ are shown as being temporally separated, but are not limited thereto and may be performed simultaneously in some time intervals according to embodiments.

From time t59 to time t60, the chip enable signal CA_CE is maintained at a logic low level, and the storage controller may provide a select chip enable command SCE for the 1-n non-volatile memory device 100_1n″ to the 1-1 to 1-n non-volatile memory devices 100_11″ to 100_1n″ through the a-th pin Pa.

At the t60 time point, based on the select chip enable command SCE, the NTO operation for the 1-n non-volatile memory device 100_1n″ is disabled and the self-termination operation for the 1-n non-volatile memory device 100_1n″ is enabled, so that the termination resistor for the data pin of the 1-n non-volatile memory device 100_1n″ may be set to the read target termination resistance Rtr. From time t60 to time t61, the 1-n non-volatile memory device 100_1n″ may output a data signal DQ of the 3-n read data RDATA3n through the data pin based on the third read command RCMD3 as a target memory device, and the read enable signal nRE may be toggled. At time t60, the chip enable signal CA_CE transitions from a logic low level to a logic high level and is maintained at the logic high level until time t61, so that the 1-1 to 1-n non-volatile memory devices 100_11″ to 100_1n″ may be deselected(DES) upon input of the command address signal CA from time t60 to time t61.

At time t61, the chip enable signal CA_CE transitions from a logic high level to a logic low level, and from time t61 to time t62, the storage controller may provide a select chip terminate command SCT for the 1-n non-volatile memory device 100_1n″ to the 1-1 to 1-n non-volatile memory devices 100_11″ to 100_1n″ through the a-th pin Pa. In FIG. 21, the output of the data signal DQ for the 3-n read data RDATA3n and the output of the select chip terminate command SCT for the 1-n non-volatile memory device 100_1n″ are depicted as being temporally separated, but are not limited thereto and may be performed simultaneously in some time intervals according to embodiments.

At time t62, a self-termination operation for the 1-n non-volatile memory device 100_1n″ is disabled and an NTO operation for the 1-n non-volatile memory device 100_1n″ is enabled based on a select chip terminate command SCT, and a termination resistor for a data pin of the 1-n non-volatile memory device 100_1n″ may be set to a read non-target termination resistance Rntr. From time t62 to time t63, the storage controller may provide an NTO disable command NTO_DIS for all of the 1-1 to 1-n non-volatile memory devices 100_11″ to 100_1n″ to the 1-1 to 1-n non-volatile memory devices 100_11″ to 100_1n″ through the a-th pin Pa. The NTO disable command NTO_DIS transmitted and received from time point t62 to time point t63 may be based on the third read command RCMD3.

At time t63, based on the NTO disable command NTO_DIS, the NTO operation for the 1-1 to 1-n non-volatile memory devices 100_11″ to 100_1n″ is disabled, so that the termination resistor for the data pins of the 1-1 to 1-n non-volatile memory devices 100_11″ to 100_1n″ may be set to an idle resistance Ridle.

In a fifth data input/output period Tio5 for the 1-1 to 1-n non-volatile memory devices 100_11″ to 100_1n″ based on a third read command RCMD3, an NTO operation for the first to first n non-volatile memory devices 100_11″ to 100_1n″ may be controlled by an NTO enable command NTO_EN and an NTO disable command NTO_DIS as well as a select chip enable command SCE and a select chip terminate command SCT. By controlling the NTO operation by the NTO enable command NTO_EN, the NTO disable command NTO_DIS, the select chip enable command SCE, and the select chip terminate command SCT as described above, the 1-1 to 1-n non-volatile memory devices 100_11″ to 100_1n″ may efficiently perform data input/output operations in the fifth data input/output period Tio5.

The storage device may disable the NTO operation for the 1-1 to 1-n non-volatile memory devices 100_11″ to 100_1n″ based on an NTO disable command NTO_DIS for all of the 1-1 to 1-n non-volatile memory devices 100_11″ to 100_1n″, instead of the NTO signal NTOs transitioning to a logic high level at a time point t64 after a time point t63. In the fifth data input/output period Tio5 for the first to first n non-volatile memory devices 100_11″ to 100_1n″ based on the third read command RCMD3, the NTO operation for the first to first n non-volatile memory devices 100_11″ to 100_1n″ may be controlled by an NTO enable command NTO_EN and an NTO disable command NTO_DIS as well as an NTO signal NTOs. By controlling the NTO operation by the NTO enable command NTO_EN, NTO disable command NTO_DIS, and NTO signal NTOs as described above, the NTO operation may be advantageously performed depending on the operating status of the storage device, thereby efficiently performing data input/output operations in the fifth data input/output period Tio5.

From time t63 to time t65, the storage controller may provide an NTO enable command NTO_EN to all of the 1-1 to 1-n non-volatile memory devices 100_11″ to 100_1n″ through the a-th pin Pa. The NTO enable command NTO_EN transmitted and received from time point t63 to time point t65 may be based on the third program command WCMD3.

At time t65, based on the NTO enable command NTO_EN, the NTO operation for the 1-1 to 1-n non-volatile memory devices 100_11″ to 100_1n″ is enabled, so that the termination resistor for the data pin of the 1-1 to 1-n non-volatile memory devices 100_11″ to 100_1n″ may be set to a write non-target termination resistance Rntw.

The storage device may enable an NTO operation for the 1-1 to 1-n non-volatile memory devices 100_11″ to 100_1n″ based on an NTO enable command NTO_EN for all of the 1-1 to 1-n non-volatile memory devices 100_11″ to 100_1n″, instead of an NTO signal NTOs that transitions to a logic low level at a time point t66 after a time point t65.

From time t65 to time t67, the storage controller may provide a select chip enable command SCE for the 1-1 non-volatile memory device 100_11″ to the 1-1 to 1-n non-volatile memory devices 100_11″ to 100_1n″ through the a-th pin Pa. Although the NTO operation is enabled and the select chip enable command SCE is output without a time interval after the output of the NTO enable command NTO_EN in FIG. 21, it is not limited thereto, and depending on the embodiment, there may be a time interval between the output of the NTO enable command NTO_EN and the enablement of the NTO operation, and between the output of the NTO enable command NTO_EN and the output of the select chip enable command SCE.

After the t67 time point, in the sixth data input/output period Tio6, the 1-1 to 1-n non-volatile memory devices 100_11″ to 100_1n″ may perform an input operation of a data signal DQ based on a third program command WCMD3 by controlling the NTO operation by the NTO enable command NTO_EN, the NTO disable command NTO_DIS, the select chip enable command SCE, the select chip terminate command SCT, and the NTO signal NTOs.

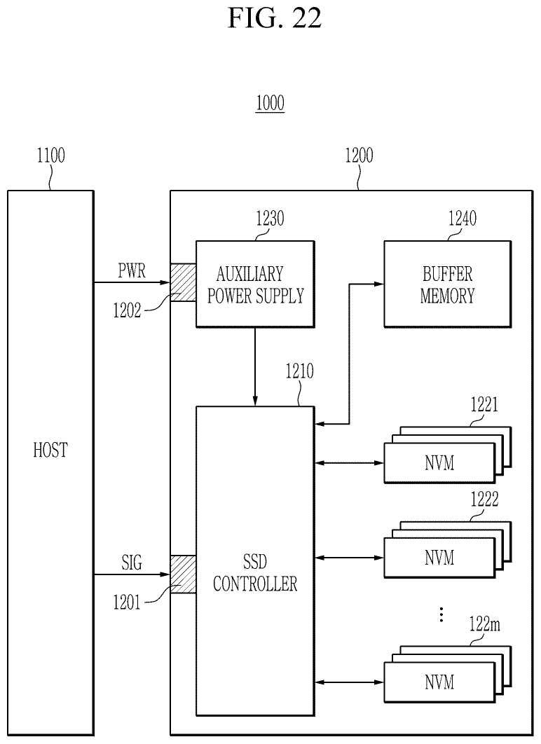

FIG. 22 is a block diagram illustrating an SSD system to which a storage device is applied according to some embodiments. Referring to FIG. 22, the SSD system 1000 includes a host 1100 and an SSD 1200.

The SSD 1200 may exchange signals SIG with the host 1100 through the signal connector 1201 and receive power PWR through the power connector 1202. The SSD 1200 may include an SSD controller 1210, a plurality of flash memories 1221 to 122m, an auxiliary power supply 1230, and a buffer memory 1240. A plurality of flash memories 1221 to 122m may be respectively connected to the SSD controller 1210 through a plurality of channels.

The SSD controller 1210 may control the plurality of flash memories 1221 to 122m in response to a signal SIG received from the host 1100. The SSD controller 1210 may store a signal generated internally or transmitted from the outside (e.g., a signal (SIG) received from the host 1100) in the buffer memory 1240.

The SSD controller 1210 may be implemented as a storage controller described above with reference to FIGS. 1 to 21. For example, the SSD controller 1210 may transmit commands/addresses through pins that are different from those that transmit data through one channel. The SSD controller 1210 may control the NTO operation of a plurality of flash memories 1221 to 122m by providing NTO packets such as an NTO enable command and an NTO disable command, as well as a select chip enable command, a select chip terminate command, and an NTO signal through pins different from the pins that transmit data. The SSD controller 1210 may improve the efficiency of data input/output operations through an NTO packet, a select chip enable command, a select chip terminate command, and an NTO signal.

Multiple flash memories 1221 to 122m may operate under the control of the SSD controller 1210. The auxiliary power supply 1230 is connected to the host 1100 via a power connector 1202. Each of the plurality of flash memories 1221 to 122m may be implemented as a non-volatile memory device as described above with reference to FIGS. 1 to 21. For example, each of the plurality of flash memories 1221 to 122m may receive commands/addresses through pins that are different from the pins that receive data. Multiple flash memories 1221 to 122m may perform NTO operation by NTO packet as well as select chip enable command, select chip terminate command, and NTO signal.

The auxiliary power supply 1230 may be connected to the host 1100 via the power connector 1202. The auxiliary power supply 1230 may receive power PWR from the host 1100 and charge it. The auxiliary power supply 1230 may provide power to the SSD 1200 when the power supply from the host 1100 is not smooth.

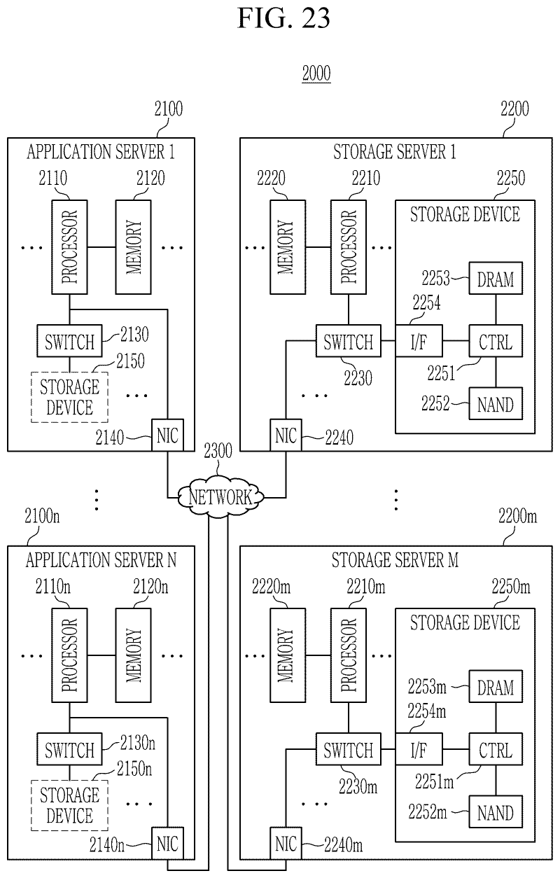

FIG. 23 is a block diagram illustrating a data center to which a storage device according to some embodiments is applied. Referring to FIG. 23, the network system 2000 is a facility that collects various types of data and provides services, and may be referred to as a data center or data storage center. The network system 2000 may include application servers 2100 to 2100n and storage servers 2200 to 2200m, and the application servers 2100 to 2100n and storage servers 2200 to 2200m may be referred to as computing nodes. The number of application servers 2100 to 2100n and the number of storage servers 2200 to 2200m may be variously selected depending on the embodiment, and the number of application servers 2100 to 2100n and the number of storage servers 2200 to 2200m may be different from each other.

Application servers 2100 to 2100n and storage servers 2200 to 2200m may communicate with each other via a network 2300. The network 2300 may be implemented using FC (Fibre Channel) or Ethernet. At this time, FC is a medium used for high-speed data transmission, and an optical switch that provides high performance/high availability may be used. Depending on the access method of the network 2300, the storage servers 2200 to 2200m may be provided as file storage, block storage, or object storage.

In an embodiment, the network 2300 may be a storage-only network, such as a Storage Area Network (SAN). For example, the SAN may be an FC-SAN that utilizes an FC network and is implemented according to the FC Protocol FCP. In an embodiment, the SAN may be an IP-SAN utilizing a TCP/IP network and implemented according to the iSCSI (SCSI over TCP/IP or Internet SCSI) protocol. In an embodiment, the network 2300 may be a general network, such as a TCP/IP network. For example, the network 2300 may be implemented according to protocols such as FCoE (FC over Ethernet), NAS (Network Attached Storage), and NVMe-oF (NVMe over Fabrics).

Below, the explanation will focus on the application server 2100 and the storage server 2200. The description of the application server 2100 may also apply to other application servers 2100n, and the description of the storage server 2200 may also apply to other storage servers 2200m.

The application server 2100 may include a processor 2110 and memory 2120. The processor 2110 may control the overall operation of the application server 2100 and access the memory 2120 to execute instructions and/or data loaded into the memory 2120. Depending on the embodiment, the number of processors 2110 and the number of memories 2120 included in the application server 2100 may be selected in various ways. In an embodiment, the processor 2110 and memory 2120 may be configured as a processor-memory pair. In an embodiment, the number of processors 2110 and memories 2120 may be configured differently.

The application server 2100 may further include a storage device 2150. At this time, the number of storage devices 2150 included in the application server 2100 may be selected in various ways depending on the embodiment. The processor 2110 may provide commands to the storage device 2150, and the storage device 2150 may operate in response to the commands received from the processor 2110. However, the present disclosure is not limited thereto, and the application server 2100 may not include a storage device 2150.

The application server 2100 may further include a switch 2130 and a network interface card (NIC) 2140. The switch 2130 may selectively connect the processor 2110 and the storage device 2150 or selectively connect the NIC 2140 and the storage device 2150 under the control of the processor 2110. The NIC 2140 may include a wired interface, a wireless interface, a Bluetooth interface, an optical interface, etc. In an embodiment, the processor 2110 and the NIC 2140 may be integrated into one. In an embodiment, the storage device 2150 and the NIC 2140 may be integrated into one.

The application server 2100 may store data requested to be stored by a user or client in one of the storage servers 2200 to 2200m via a network 2300. Additionally, the application server 2100 may obtain data requested by a user or client from one of the storage servers 2200 to 2200m through the network 2300. For example, the application server 2100 may be implemented as a web server or a DBMS (Database Management System).

An application server 2100 may access a memory 2120n or a storage device 2150n included in another application server 2100n via a network 2300, or may access a memory 2220, 2220m or a storage device 2250, 2250m included in a storage server 2200, 2200m via a network 2300. Accordingly, the application server 2100 may perform various operations on data stored in the application server 2100, 2100n and/or the storage server 2200, 2200m. For example, the application server 2100 may execute commands to move or copy data between application servers 2100, 2100n and/or storage servers 2200, 2200m. In this case, data may be transferred over the network 2300 in an encrypted state for security or privacy.

The storage server 2200 may include a processor 2210 and memory 2220. The processor 2210 may control the overall operation of the storage server 2200 and access the memory 2220 to execute commands and/or data loaded into the memory 2220. Depending on the embodiment, the number of processors 2210 and the number of memories 2220 included in the storage server 2200 may be selected in various ways. In an embodiment, the processor 2210 and the memory 2220 may be configured as a processor-memory pair. In an embodiment, the number of processors 2210 and memories 2220 may be configured differently.

The processor 2210 may include a single core processor or a multi-core processor. For example, the processor 2210 may include a general-purpose processor, a CPU (Central Processing Unit), a GPU (Graphics Processing Unit), a DSP (Digital Signal Processor), an MCU(Microcontroller), a microprocessor, a network processor, an embedded processor, an FPGA (field programmable gate array), an ASIP (application-specific instruction set processor), an ASIC (application-specific integrated circuit processor), etc.

The storage server 2200 may further include at least one storage device 2250. The number of storage devices 2250 included in the storage server 2200 may be selected in various ways depending on the embodiment. The storage device 2250 may include a controller (CTRL) 2251, a plurality of NAND flashes (NAND) 2252, DRAM 2253, and an interface (I/F) 2254. Below, the configuration and operation of the storage device 2250 will be described. The following description of the storage device 2250 may also apply to other storage devices (2150, 2150n, 2250m).

The interface 2254 may provide a physical connection between the processor 2210 and the controller 2251 and a physical connection between the NIC 2240 and the controller 2251. For example, the interface 2254 may be implemented in a DAS (Direct Attached Storage) manner that directly connects the storage device 2250 with a dedicated cable. Additionally, for example, the interface 2254 may be implemented in various interface methods such as ATA (Advanced Technology Attachment), SATA (Serial ATA), e-SATA (external SATA), SCSI (Small Computer Small Interface), SAS (Serial Attached SCSI), PCI (Peripheral Component Interconnection), PCIe (PCI express), NVMe (NVM express), IEEE 1394, USB (universal serial bus), SD (secure digital) card, MMC (multi-media card), eMMC (embedded multi-media card), CF (compact flash) card interface, etc.

The controller 2251 may control the overall operation of the storage device 2250. The controller 2251 may program data into a plurality of NAND flashes 2252 in response to a program command, or read data from a plurality of NAND flashes 2252 in response to a read command. For example, the program commands and/or read commands may be provided through or directly to the processor 2210 from a processor 2210 within a storage server 2200, a processor 2210m within another storage server 2200m, or a processor 2110, 2110n within an application server 2100, 2100n.

The plurality of NAND flashes 2252 may include a plurality of NAND flash memory cells. In some embodiments, the plurality of NAND flashes 2252 may include the plurality of non-volatile memories connected to one channel. However, the present disclosure is not limited thereto, and the storage device 2250 may include non-volatile memory other than NAND flash 2252, for example, ReRAM (resistive RAM), PRAM (phase change RAM), or MRAM (magnetic RAM), or may include a magnetic storage medium or an optical storage medium, etc.

DRAM (Dynamic RAM) 2253 may be used as buffer memory. For example, the DRAM 2253 may be DDR SDRAM (Double Data Rate Synchronous DRAM), LPDDR (Low Power DDR) SDRAM, GDDR (Graphics DDR) SDRAM, RDRAM (Rambus DRAM), or HBM (High Bandwidth Memory). However, the present disclosure is not limited thereto, and the storage device 2250 may use volatile memory or non-volatile memory other than DRAM as a buffer memory. DRAM 2253 may temporarily store (buffer) data to be written to the plurality of NAND flashes 2252 or data read from the plurality of NAND flashes 2252.

The storage server 2200 may further include a switch 2230 and a NIC 2240. The switch 2230 may selectively connect the processor 2210 and the storage device 2250 or selectively connect the NIC 2240 and the storage device 2250 under the control of the processor 2210. In an embodiment, the processor 2210 and the NIC 2240 may be integrated into one. In an embodiment, the storage device 2250 and the NIC 2240 may be integrated into one.

The storage devices (2150, 2150n, 2250, 2250m) may correspond to the storage devices described above with reference to FIGS. 1 to 21. For example, the controller 2251 may transmit commands/addresses to the plurality of NAND flashes 2252 in response to a request provided from one of the processors (2110, 2110n, 2210, 2210m). The controller 2251 may transmit commands/addresses through pins that are different from the pins that transmit data. The controller 2251 may control the NTO operation of the plurality of NAND flashes 2252 by providing NTO packets such as an NTO enable command and an NTO disable command, as well as a select chip enable command, a select chip terminate command, and an NTO signal through pins different from the pins transmitting data. The controller 2251 may improve the efficiency of data input/output operations through NTO packets, select chip enable commands, select chip terminate commands, and NTO signals.

Although the embodiments of the present disclosure have been described in detail above, the scope of the present disclosure is not limited thereto, and various modifications and improvements made by those skilled in the art using the basic concept of the present disclosure defined in the following claims also fall within the scope of the present disclosure.

1. A non-volatile memory device comprising:
a data pin configured to output a data signal;
a command address pin separated from the data pin and configured to receive a NTO (Non-Target On Die Termination) enable command for a non-target termination resistance of the data pin and a select chip enable command for an output operation of the data signal; and
an on die termination circuit configured to set a termination resistor for the data pin to the non-target termination resistance, in response to a logical operation of NTO enable data based on the NTO enable command and select chip enable data based on the select chip enable command.

2. The non-volatile memory device of claim 1, wherein:
the on die termination circuit includes an NTO enable circuit configured to generate an ODT (On Die Termination) control signal based on a logical AND operation on inverted data of the select chip enable data and the NTO enable data.

3. The non-volatile memory device of claim 2, wherein:
the on die termination circuit is configured to set the termination resistor for the data pin to a target termination resistance different from the non-target termination resistance, in response to receiving the select chip enable command.

4. The non-volatile memory device of claim 2, wherein:
the on die termination circuit includes a chip selection circuit configured to generate the select chip enable data based on the select chip enable command and a non-target ODT control circuit configured to generate the NTO enable data based on the NTO enable command.

5. The non-volatile memory device of claim 4, wherein:
the non-target ODT control circuit is configured to generate the NTO enable data at a logic high level based on the NTO enable command.

6. The non-volatile memory device of claim 4, wherein:
the on die termination circuit is configured to receive an NTO disable command for the non-target termination resistance through the command address pin,
the non-target ODT control circuit is configured to output the NTO enable data at a logic low level based on the NTO disable command.

7. The non-volatile memory device of claim 2, wherein:
the NTO enable circuit includes an AND operator configured to perform a logical AND operation on inverted data of the select chip enable data and the NTO enable data, and a flip-flop configured to generate the ODT control signal in response to a rising edge of a result value of the AND operator.

8. The non-volatile memory device of claim 7, wherein:
the NTO enable circuit further includes an OR operator configured to perform a logical OR operation on a pulse signal for a falling edge of the NTO enable data and a pulse signal for a rising edge of the select chip enable data,
the flip-flop is configured to receive the result value of the AND operator as a reset signal.

9. The non-volatile memory device of claim 1, wherein:
the on die termination circuit is configured to set the termination resistor to an idle resistance different from the non-target termination resistance in response to receiving an NTO disable command for the non-target termination resistance.

10. The non-volatile memory device of claim 1, further comprising:
an NTO pin separated from the data pin and the command address pin and configured to receive an NTO signal for the non-target termination resistance;
the on die termination circuit is configured to set the termination resistor to the non-target termination resistance in response to a logical operation on NTO data based on the NTO signal, the NTO enable data, and the select chip enable data.

11. The non-volatile memory device of claim 1, wherein:
the on die termination circuit includes a non-target ODT control circuit configured to generate the NTO data based on the NTO signal.

12. The non-volatile memory device of claim 10, wherein:
the on die termination circuit further includes an OR operator configured to perform a logical OR operation on the NTO enable data and the NTO data, an AND operator configured to perform a logical AND operation on the inverted data of the select chip enable data and a result value of the AND operator, and a flip-flop configured to generate an ODT control signal in response to a transition of the result value of the AND operator.

13. A storage device comprising:
a first non-volatile memory device including a first data pin, a first command address pin separated from the first data pin, and a first on die termination circuit;
a second non-volatile memory device including a second data pin electrically connected to the first data pin through a channel, a second command address pin separated from the second data pin, and a second on die termination circuit; and
a storage controller configured to provide an NTO enable command for enabling an NTO operation of the first on die termination circuit and the second on die termination circuit to the first non-volatile memory device and the second non-volatile memory device, respectively, through the first command address pin and the second command address pin to enable an NTO operation for the first data pin, and provide a first select chip enable command for an output operation of the first data pin through the first command address pin to control the first on die termination circuit to disable the NTO operation for the first data pin.

14. The storage device of claim 13, wherein:
the storage controller is configured to sequentially provide the NTO enable command and the first select chip enable command to the first non-volatile memory device.

15. The storage device of claim 13, wherein:
the storage controller is configured to provide a first select chip terminate command corresponding to the first select chip enable command to control the first on die termination circuit to enable an NTO operation for the first data pin.

16. The storage device of claim 15, wherein:
the storage controller is configured to provide a second select chip enable command for an output operation of the second data pin through the second command address pin after providing the first select chip terminate command to control the second on die termination circuit to disable an NTO operation for the second data pin.

17. A method of operating a storage device comprising:
providing a read command to a first non-volatile memory device and a second non-volatile memory device sharing a channel with each other;
providing an NTO (Non-Target On Die Termination) enable command to the first non-volatile memory device and the second non-volatile memory device through a first command address pin of the first non-volatile memory device and a second command address pin of the second non-volatile memory device to enable an NTO operation for a first data pin separated from the first command address pin in the first non-volatile memory device and an NTO operation for a second data pin separated from the second command address pin in the second non-volatile memory device;
providing a first select chip enable command for an output operation of the first data pin through the first command address pin to disable an NTO operation for the first data pin and enable a self-termination operation for the first data pin;
outputting a first data signal from the first data pin of the first non-volatile memory device; and
providing a first select chip terminate command corresponding to the first select chip enable command through the first command address pin to disable the self-termination operation for the first data pin and enable the NTO operation for the first data pin.

18. The method of operating the storage device of claim 17, further comprising:
providing a second select chip enable command for an output operation of the second data pin through the second command address pin, to disable an NTO operation for the second data pin and enable a self-termination operation for the second data pin; and
outputting a second data signal from the second data pin of the second non-volatile memory device.

19. The method of operating the storage device of claim 17, further comprising:
confirming completion of an output operation for the read command in response to the output of the first data signal.

20. The method of operating the storage device of claim 19, further comprising:
providing an NTO disable command to the first and second non-volatile memory devices through the first command address pin and the second command address pin in response to completion of an output operation for the read command, to disable an NTO operation for the first data pin and an NTO operation for the second data pin.

21. (canceled)
